(19) United States
(12) Patent Application Publication
(10) Pub. No.: US 2022/0004102 A1
(43) Pub. Date: Jan. 6, 2022

(54) TRANSFER FILM FOR SILVER CONDUCTIVE MATERIAL PROTECTIVE FILM, MANUFACTURING METHOD OF PATTERNED SILVER CONDUCTIVE MATERIAL, LAMINATE, AND TOUCH PANEL

(71) Applicant: FUJIFILM CORPORATION, Tokyo (JP)

(72) Inventors: Daisuke HIRAKI, Fujinomiya-shi (JP); Yohei ARITOSHI, Fujinomiya-shi (JP); Kentaro TOYOOKA, Fujinomiya-shi (JP); Keigo UEKI, Fujinomiya-shi (JP)

(21) Appl. No.: 17/480,157

(22) Filed: Sep. 21, 2021

Related U.S. Application Data
(63) Continuation of application No. PCT/JP2020/013859, filed on Mar. 26, 2020.

(51) Int. Cl. G03F 7/09; G06F 3/041; H01B 5/14; H01B 1/02; H01B 13/00; G03F 7/032; G03F 7/16

(52) U.S. Cl. CPC G03F 7/09; G06F 3/0412; H01B 5/14; G06F 2203/04103; H01B 13/0036; G03F 7/032; G03F 7/161; H01B 1/02

(57) ABSTRACT

Provided are a transfer film for a silver conductive material protective film, including a temporary support, and a photosensitive layer which is provided on the temporary support, and includes at least one selected from the group consisting of a binder polymer and a polymerizable compound, and a photopolymerization initiator, in which an amount of free chloride ions included in the photosensitive layer is 20 ppm or less, and a mass content average value of C log P values in all the binder polymer and polymerizable compound included in the photosensitive layer is 2.75 or more; a manufacturing method of a patterned silver conductive material using the transfer film for a silver conductive material protective film; a laminate including, in the following order, a substrate, a silver conductive material, and a cured resin layer, in which an amount of free chloride ions included in the cured resin layer is 20 ppm or less, and a C log P value of a cured resin component included in the cured resin layer is 2.75 or more; and a touch panel.

### CROSS-REFERENCE TO RELATED APPLICATIONS

This application is a continuation application of International Application No. PCT/JP2020/013859, filed Mar. 26, 2020, the disclosure of which is incorporated herein by reference in its entirety. Further, this application claims priority from Japanese Patent Application No. 2019-058924, filed Mar. 26, 2019, Japanese Patent Application No. 2019-148852, filed Aug. 14, 2019, and Japanese Patent Application No. 2019-167254, filed Sep. 13, 2019, the disclosures of which are incorporated herein by reference in their entireties.

### BACKGROUND OF THE INVENTION

### 1. Field of the Invention

The present disclosure relates to a transfer film for a silver conductive material protective film, a manufacturing method of a patterned silver conductive material, a laminate, and a touch panel.

### 2. Description of the Related Art

In recent years, in electronic devices such as a mobile phone, a car navigator, a personal computer, a ticket vending machine, or a terminal of the bank, a tablet-type input device is disposed on a surface of a liquid crystal device or the like. In such an electronic device, while referring to an instruction image displayed in an image display region of a liquid crystal device, information corresponding to the instruction image can be input by touching a portion where the instruction image is displayed, with a finger or a touch pen.

The input device described above (hereinafter, also referred to as a “touch panel”) includes a resistance film-type input device, an electrostatic capacity-type input device, and the like. The capacitive input device is advantageous in that a transmittance conductive film may be simply formed on one sheet of substrate. As such a capacitive input device, for example, there is a device in which electrode patterns are extended in directions intersecting each other, and which detects an input position by detecting a change of electrostatic capacity between electrodes, in a case where a finger or the like is touched.

In order to protect electrode patterns or lead wire (for example, metal wire such as copper wire) put together on a frame portion of the capacitive input device, a transparent resin layer is provided on a side opposite to the surface for the inputting with a finger or the like. A photosensitive resin composition is used as a material for forming such a transparent resin layer.

For example, JP2014-141592A discloses a composition for forming a protective film, containing a reducing compound (A) having a specific structure; at least one compound (B) which has a structure selected from the group consisting of a triazole structure, a thiadiazole structure, and a benzimidazole structure, a mercapto group, and a hydrocarbon group which may have a heteroatom, in which the total number of carbon atoms in the hydrocarbon group (in a case of a plurality of the hydrocarbon groups, the total number of carbon atoms in each hydrocarbon group) is 5 or more; a transparent resin (C); and a polymerizable compound (D).

### SUMMARY OF THE INVENTION

One embodiment according to the present disclosure relates to providing a transfer film for a silver conductive material protective film, which has a small resistance change of a silver conductive material after a wet heat test.

Another embodiment according to the present disclosure relates to providing a laminate having a small resistance change of a silver conductive material after a wet heat test, and a touch panel.

Still another embodiment according to the present disclosure relates to providing a manufacturing method of a patterned silver conductive material using the transfer film for a silver conductive material protective film.

The present disclosure includes the following aspects.

<1> A transfer film for a silver conductive material protective film, comprising:

a temporary support; and

a photosensitive layer which is provided on the temporary support, and includes at least one selected from the group consisting of a binder polymer and a polymerizable compound, and a photopolymerization initiator,

in which an amount of free chloride ions included in the photosensitive layer is 20 ppm or less, and

a mass content average value of C log P values in all the binder polymer and polymerizable compound included in the photosensitive layer is 2.75 or more.

<2> The transfer film according to <1>,

in which the amount of free chloride ions is 15 ppm or less.

<3> The transfer film according to <1> or <2>,

in which the amount of free chloride ions is 10 ppm or less.

<4> The transfer film according to any one of <1> to <3>,

in which the amount of free chloride ions is 5 ppm or less.

<5> The transfer film according to any one of <1> to <4>,

in which the mass content average value of C log P values in all the binder polymer and polymerizable compound included in the photosensitive layer is 3.15 or more.

<6> The transfer film according to any one of <1> to <5>,

in which a thickness of the photosensitive layer is in a range of 0.05 μm to 10 μm.

<7> The transfer film according to any one of <1> to <6>, further comprising:

a second resin layer between the temporary support and the photosensitive layer.

<8> The transfer film according to any one of <1> to <7>, in which the binder polymer in the photosensitive layer includes an alkali-soluble resin.

<9> A manufacturing method of a patterned silver conductive material, comprising in the following order:

a step of transferring at least the photosensitive layer of the transfer film according to any one of <1> to <8> to a substrate having a silver conductive material on a surface;

a step of performing a pattern exposure of the photosensitive layer; and

a step of developing the photosensitive layer to form a pattern.

<10> A laminate comprising in the following order:

a substrate;

a silver conductive material; and

a cured resin layer,

in which an amount of free chloride ions included in the cured resin layer is 20 ppm or less, and

a C log P value of a cured resin component included in the cured resin layer is 2.75 or more.

<11> A touch panel comprising:

the laminate according to <10>.

<12> A manufacturing method of a patterned silver conductive material, comprising in the following order:

a step of preparing a substrate;

a step of forming an electrode for a touch panel on the substrate with a silver conductive material; and

a step of forming a metal layer on the substrate having the electrode for a touch panel,

in which the manufacturing method further includes
a step of treating the metal layer with a treatment liquid containing at least one azole compound selected from the group consisting of an imidazole compound, a triazole compound, a tetrazole compound, a thiazole compound, and a thiadiazole compound, and
a step of forming a wire for a touch panel from the metal layer, and

the manufacturing method further includes, in the following order,
a step of attaching at least the photosensitive layer in the transfer film according to any one of <1> to <8> to the wire for a touch panel and the substrate having the electrode for a touch panel,
a step of performing a pattern exposure of the photosensitive layer, and
a step of developing the photosensitive layer to form a pattern.

<13> A manufacturing method of a patterned silver conductive material, comprising in the following order:

a step of preparing a substrate; and

a step of forming a metal layer on the substrate,

in which the manufacturing method further includes
a step of treating the metal layer with a treatment liquid containing at least one azole compound selected from the group consisting of an imidazole compound, a triazole compound, a tetrazole compound, a thiazole compound, and a thiadiazole compound, and
a step of forming a wire for a touch panel from the metal layer, and

the manufacturing method further includes, in the following order,
a step of forming an electrode for a touch panel with a silver conductive material on the substrate on a side of the wire for a touch panel,
a step of attaching at least the photosensitive layer in the transfer film according to any one of <1> to <8> to the wire for a touch panel and the substrate having the electrode for a touch panel,
a step of performing a pattern exposure of the photosensitive layer, and
a step of developing the photosensitive layer to form a pattern.

<14> The manufacturing method of a patterned silver conductive material according to <12> or <13>,

in which a pKa of a conjugate acid of the at least one azole compound selected from the group consisting of an imidazole compound, a triazole compound, a tetrazole compound, a thiazole compound, and a thiadiazole compound is 4.00 or less.

According to one embodiment according to the present disclosure, it is possible to provide a transfer film for a silver conductive material protective film, which has a small resistance change of a silver conductive material after a wet heat test.

According to another embodiment according to the present disclosure, it is possible to provide a laminate having a small resistance change of a silver conductive material after a wet heat test, and a touch panel.

According to still another embodiment according to the present disclosure, it is possible to provide a manufacturing method of a patterned silver conductive material using the transfer film for a silver conductive material protective film.

### BRIEF DESCRIPTION OF THE DRAWINGS

FIG. 1 is a schematic cross-sectional view showing an example of a transfer film for a silver conductive material protective film according to an embodiment of the present disclosure.

FIG. 2 is a schematic cross-sectional view showing one specific example of the touch panel according to an embodiment of the present disclosure.

FIG. 3 is a schematic cross-sectional view showing another specific example of the touch panel according to an embodiment of the present disclosure.

### DESCRIPTION OF THE PREFERRED EMBODIMENTS

Hereinafter, the content of the present disclosure will be described in detail. The configuration requirements will be described below based on the representative embodiments of the present disclosure, but the present disclosure is not limited to such embodiments.

In the present disclosure, a term “to” showing a range of numerical values is used as a meaning including a lower limit value and an upper limit value disclosed before and after the term.

In a range of numerical values described in stages in this specification, the upper limit value or the lower limit value described in one range of numerical values may be replaced with an upper limit value or a lower limit value of the range of numerical values described in other stages. In addition, in a range of numerical values described in this specification, the upper limit value or the lower limit value of the range of numerical values may be replaced with values shown in the examples.

Regarding a term, group (atomic group) of this present disclosure, a term with no description of “substituted” and “unsubstituted” includes both a group not including a substituent and a group including a substituent. For example, an “alkyl group” not only includes an alkyl group not including a substituent (unsubstituted alkyl group), but also an alkyl group including a substituent (substituted alkyl group).

In addition, in the present disclosure, “% by mass” is identical to “% by weight” and “part by mass” is identical to “part by weight”.

Further, in the present disclosure, a combination of two or more preferable aspects is the more preferable aspects.

In the present disclosure, in a case where a plurality of substances corresponding to components are present in a composition, an amount of each component in the composition means a total amount of the plurality of substances present in the composition, unless otherwise noted.

In the present disclosure, a term “step” not only includes an independent step, but also includes a step, in a case where the step may not be distinguished from the other step, as long as the expected object of the step is achieved.

In the present disclosure, “(meth)acrylic acid” has a concept including both acrylic acid and a methacrylic acid, “(meth)acrylate” has a concept including both acrylate and methacrylate, and “(meth)acryloyl group” has a concept including both acryloyl group and methacryloyl group.

A weight-average molecular weight (Mw) and a number average molecular weight (Mn) of the present disclosure, unless otherwise noted, are detected by a gel permeation chromatography (GPC) analysis apparatus using a column of TSKgel GMHxL, TSKgel G4000HxL, TSKgel G2000HxL (all product names manufactured by Tosoh Corporation), by using tetrahydrofuran (THF) as a solvent and a differential refractometer, and are molecular weights obtained by conversion using polystyrene as a standard substance.

In the present disclosure, unless otherwise specified, a molecular weight of a compound having a molecular weight distribution is the weight-average molecular weight.

In the present disclosure, unless otherwise specified, a ratio of constitutional units of a polymer is a molar ratio.

In the present disclosure, unless otherwise specified, a refractive index is a value at a wavelength of 550 nm measured at 25° C. with an ellipsometer.

Hereinafter, the present disclosure will be described in detail.

(Transfer Film for Silver Conductive Material Protective Film)

The transfer film for a silver conductive material protective film (hereinafter, also simply referred to as a “transfer film”) according to the embodiment of the present disclosure includes a temporary support, and a photosensitive layer which is provided on the temporary support, and includes at least one selected from the group consisting of a binder polymer and a polymerizable compound, and a photopolymerization initiator, in which an amount of free chloride ions included in the photosensitive layer is 20 ppm or less, and a mass content average value of C log P values in all the binder polymer and polymerizable compound included in the photosensitive layer is 2.75 or more.

As a result of intensive studies, the present inventors have found that it is possible to provide a transfer film for a silver conductive material protective film, which has a small resistance change of a silver conductive material after a wet heat test, by using the above-described configuration.

An operation mechanism for excellent effect by this is not clear, but is assumed as follows.

Since the amount of free chloride ions included in the above-described photosensitive layer is 20 ppm or less, and the mass content average value of C log P values in all the binder polymer and polymerizable compound included in the above-described photosensitive layer is 2.75 or more, it is possible to suppress production of silver chloride due to contact with chloride ions which are highly reactive with silver, the production being a reaction that proceeds particularly easily at high temperatures. In addition, since the mass content average value of C log P values in the binder polymer and polymerizable compound included in the above-described photosensitive layer is set to the above-describe range, thereby setting the inside of the photosensitive layer to be more hydrophobic, the ingress of moisture (water) in the photosensitive layer after curing is suppressed. Therefore, it is possible to suppress an oxidation reaction of silver, which tends to proceed in a moist environment, and to suppress production of silver oxide. Further, the production of silver chloride can be suppressed by suppressing the movement of chloride ions accompanying the movement of water and by reducing the contact probability between silver and chloride ions. It is assumed that the above-described mechanism can reduce a resistance change of the silver conductive material after the wet heat test.

<Temporary Support>

The transfer film according to the embodiment of the present disclosure includes a temporary support.

The temporary support is preferably a film and more preferably a resin film. As the temporary support, a film which has flexibility and does not generate significant deformation, contraction, or stretching under pressure or under pressure and heating can be used.

Examples of such a film include a polyethylene terephthalate film (for example, a biaxial stretching polyethylene terephthalate film), a cellulose triacetate film, a polystyrene film, a polyimide film, and a polycarbonate film.

Among these, as the temporary support, a biaxial stretching polyethylene terephthalate film is particularly preferable.

In addition, it is preferable that the film used as the temporary support does not have deformation such as wrinkles or scratches.

From the viewpoint that pattern exposure through the temporary support can be performed, the temporary support preferably has high transparency, and the transmittance at 365 nm is preferably 60% or more and more preferably 70% or more.

From the viewpoint of pattern formation during pattern exposure through the temporary support and transparency of the temporary support, it is preferable that the haze of the temporary support is small. Specifically, the haze value of the temporary support is preferably 2% or less, more preferably 0.5% or less, and particularly preferably 0.1% or less.

From the viewpoint of pattern formation during pattern exposure through the temporary support and transparency of the temporary support, it is preferable that the number of particles, foreign substances, and defects included in the temporary support is small.

The number of particles having a diameter of 1 μm or more, foreign substances, and defects on a surface of the temporary support is preferably 50 pieces/10 mm² or less, more preferably 10 pieces/10 mm² or less, and still more preferably 3 pieces/10 mm² or less.

The thickness of the temporary support is not particularly limited, but is preferably 5 μm to 200 μm. In addition, from the viewpoint of ease of handling and general-purpose properties, the thickness of the temporary support is more preferably 10 μm to 150 μm.

Preferred aspects of the temporary support are described in, for example, paragraphs 0017 and 0018 of JP2014-85643A, paragraphs 0019 to 0026 of JP2016-27363A, paragraphs 0041 to 0057 of WO2012/081680A, and paragraphs 0029 to 0040 of WO2018/179370A, and the contents of these publications are incorporated in the present specification.

In addition, particularly preferred examples of the temporary support include a biaxial stretching polyethylene terephthalate film having a thickness of 16 μm, a biaxial stretching polyethylene terephthalate film having a thickness of 12 μm, and a biaxial stretching polyethylene terephthalate film having a thickness of 10 μm.

<Photosensitive Layer>

The transfer film according to the embodiment of the present disclosure includes a photosensitive layer which is provided on the above-described temporary support, and includes at least one selected from the group consisting of a binder polymer and a polymerizable compound, and a photopolymerization initiator, in which an amount of free chloride ions included in the photosensitive layer is 20 ppm or less, and a mass content average value of C log P values in all the binder polymer and polymerizable compound included in the photosensitive layer is 2.75 or more.

<<Amount of Free Chloride Ions>>

The amount of free chloride ions included in the above-described photosensitive layer is 20 ppm or less, and from the viewpoint of suppressing resistance change of the silver conductive material after the wet heat test or the heat test, is preferably 15 ppm or less, more preferably 10 ppm or less, still more preferably 5 ppm or less, and particularly preferably 1 ppm or less. The photosensitive layer may not include the free chloride ions, and even in a case of including the free chloride ions, the amount of free chloride ions is 20 ppm or less.

In the present disclosure, the amount of free chloride ions included in the above-described photosensitive layer or in a cured resin layer which will be described later is measured by the following method.

The photosensitive layer or the cured resin layer described later is collected as a sample of approximately 100 mg, and approximately 100 mg of the collected sample is dissolved in 5 mL of propylene glycol monomethyl ether acetate. 5 mL of ultrapure water is added thereto, and the mixture is stirred for 2 hours. The mixture is left to stand for 12 hours or more, 1 mL of the aqueous layer is collected, and 9 mL of ultrapure water is added thereto to prepare a sample for measurement.

The prepared sample for measurement is subjected to ion chromatograph according to the measuring device and measuring conditions shown below, thereby measuring and calculating the amount of free chloride ions.
Ion chromatograph device: IC-2010 (manufactured by Tosoh Corporation)
Analytical column: TSKgel SuperIC-Anion HS
Guard column: TSKgel guardcolumn SuperIC-A HS
Eluent: 1.7 mmol/L NaHCO₃ aqueous solution+1.8 mmol/L Na₂CO₃ aqueous solution
Flow rate: 1.2 mL/min
Temperature: 30° C.
Injection amount: 30 μL
Suppressor gel: TSKgel suppress IC-A
Detection: electrical conductivity (measured using a suppressor)

Examples of a method of collecting the above-described photosensitive layer used for measuring the amount of free chloride ions include a method in which a protective film is peeled off, a photosensitive resin layer on the transfer film is laminated on glass, and the temporary support is peeled off to transfer the photosensitive resin layer and collect 100 mg of the photosensitive layer.

In addition, examples of a method of collecting the cured resin layer described later include a method of scraping 100 mg from the cured resin layer and collecting the cured resin layer.

<<Mass Content Average Value of C log P Value>>

The mass content average value of C log P values in all the binder polymer and polymerizable compound included in the above-described photosensitive layer is 2.75 or more, and from the viewpoint of suppressing resistance change of the silver conductive material after the wet heat test or the heat test, is preferably 3.00 or more, more preferably 3.15 or more, still more preferably 3.50 or more, and particularly preferably 3.80 or more.

In addition, regarding the upper limit of the mass content average value of C log P values, from the viewpoint of suppressing resistance change of the silver conductive material after the wet heat test or the heat test, the mass content average value of C log P values is preferably 5.00 or less, more preferably 4.50 or less, and particularly preferably 4.00 or less. Each of these upper limit values can be freely combined with any of the above-described lower limit values.

In the present disclosure, C log P is a value that serves as an index of n-octanol/water partition coefficient (log P_{ow}) and can be obtained by software. Specifically, the calculation can be performed using ChemDraw (registered trademark) Professional (ver.16.0.1.4) manufactured by PerkinElmer Informatics. Specifically, for example, the calculation is performed as follows.

First, each C log P value of the binder polymer and polymerizable compound included in the photosensitive layer is calculated. The calculation is performed using ChemDraw Professional described above.

In addition, the calculation of a polymer is performed by converting the polymer into monomers constituting the polymer. For example, in a case of polyacrylic acid, the calculation is performed by acrylic acid, and in a case of a polyacrylic acid-polymethacrylic acid copolymer having a mass ratio of 50:50, C log P values of acrylic acid and methacrylic acid are calculated, the values are multiplied by the mass ratio (0.5 each in this case), the total value thereof is defined as the C log P value.

Next, the mass ratio is calculated by dividing the mass of each raw material by the total mass of the binder polymer and the polymerizable compound. The C log P values of each raw material are multiplied by the mass ratio, and the total value thereof is calculated and defined as the C log P value of the transfer film.

For example, in a case of Example 1 which will be described later, with regard to a compound A-1, a compound B-1, and a compound B-2, C log P values of each raw material are calculated to be 2.52, 5.13, and 5.08, and mass ratios thereof are 0.555, 0.223, and 0.222, so that 3.67, which is a value obtained by multiplying each of these values and calculating the total value, is defined as the C log P value of Example 1.

In addition, in a case where the binder polymer and the polymerizable compound included in the photosensitive layer are unknown, by transferring the photosensitive layer of the transfer film onto glass and then collecting the photosensitive layer and by performing composition analysis such as spectroscopy and NMR, each structure and ratio of the binder polymer and the polymerizable compound is confirmed. C log P values of various binder polymers and polymerizable compounds are calculated and multiplied by mass ratios, and the total value is calculated and defined as the mass content average value of C log P values in all the binder polymer and polymerizable compound included in the above-described photosensitive layer.

In addition, with regard to the cured resin layer described later, by performing composition analysis such as spectroscopy and NMR for the included cured resin component, the C log P value of the cured resin component included in the cured resin layer can be calculated. Components such as residue of the photopolymerization initiator are ignored because the content thereof is small and the influence on physical properties of the entire cured resin layer is small.

<<Binder Polymer>>

From the viewpoint of adhesiveness to the silver conductive material and hardness of a cured resin layer to be obtained, the photosensitive layer preferably includes a binder polymer and more preferably includes a binder polymer and a polymerizable compound. In addition, in a case where the photosensitive layer does not include a polymerizable compound, the binder polymer preferably includes a binder polymer having a polymerizable group (preferably, an ethylenically unsaturated group).

From the viewpoint of developability, the binder polymer preferably includes an alkali-soluble resin and is more preferably an alkali-soluble resin.

In the present disclosure, the “alkali-soluble” means that the solubility in 100 g of aqueous solution of 1% by mass sodium carbonate at 22° C. is 0.1 g or more.

From a viewpoint of developability, for example, the binder polymer is preferably a binder polymer having an acid value of 60 mgKOH/g or more and more preferably an alkali-soluble resin having an acid value of 60 mgKOH/g or more.

In addition, from the viewpoint that it is easy to form a strong film by thermally crosslinking with a crosslinking component by heating, for example, the binder polymer is still more preferably a resin (so-called a carboxy group-containing resin) having an acid value of 60 mgKOH/g or more and having a carboxy group, and particularly preferably a (meth)acrylic resin (so-called a carboxy group-containing (meth)acrylic resin) having an acid value of 60 mgKOH/g or more and having a carboxy group.

In a case where the binder polymer is a resin having a carboxy group, for example, the three-dimensional crosslinking density of a cured resin layer to be obtained can be increased by adding blocked isocyanate and thermally crosslinking. In addition, in a case where the carboxy group of the resin having a carboxy group is anhydrous and hydrophobized, wet heat resistance can be improved.

The carboxy group-containing (meth)acrylic resin (hereinafter, also referred to as a “specific polymer A”) having an acid value of 60 mgKOH/g or more is not particularly limited as long as the above-described conditions of acid value are satisfied, and a known (meth)acrylic resin can be appropriately selected and used.

For example, a carboxy group-containing (meth)acrylic resin having an acid value of 60 mgKOH/g or more among polymers described in paragraph 0025 of JP2011-95716A, a carboxy group-containing (meth)acrylic resin having an acid value of 60 mgKOH/g or more among polymers described in paragraphs 0033 to 0052 of JP2010-237589A, and the like can be preferably used as the specific polymer A in the present disclosure.

Here, the (meth)acrylic resin refers to a resin containing at least one of a constitutional unit derived from (meth)acrylic acid or a constitutional unit derived from (meth)acrylic acid ester.

The total proportion of the constitutional unit derived from (meth)acrylic acid and the constitutional unit derived from (meth)acrylic acid ester in the (meth)acrylic resin is preferably 30 mol % or more and more preferably 50 mol % or more.

The copolymerization ratio of the monomer having a carboxy group in the specific polymer A is preferably 5% by mass to 50% by mass, more preferably 5% by mass to 40% by mass, and still more preferably 10% by mass to 30% by mass with respect to 100% by mass of the specific polymer A.

In addition, from a viewpoint of moisture permeability and hardness after curing, the binder polymer (particularly, the specific polymer A) preferably has a constitutional unit having an aromatic ring.

Examples of a monomer forming the constitutional unit having an aromatic ring include styrene, tert-butoxystyrene, methylstyrene, α-methylstyrene, and benzyl (meth)acrylate.

The constitutional unit having an aromatic ring is preferably a constitutional unit derived from a styrene compound.

In a case where the binder polymer includes the constitutional unit having an aromatic ring, the content of the constitutional unit having an aromatic ring is preferably 5% by mass to 90% by mass, more preferably 10% by mass to 70% by mass, and still more preferably 20% by mass to 50% by mass with respect to the total mass of the binder polymer.

In addition, from the viewpoint of tackiness of the photosensitive layer and hardness after curing, the binder polymer (particularly, the specific polymer A) preferably has a constitutional unit having an aliphatic cyclic skeleton.

Examples of a monomer forming the constitutional unit having an aliphatic cyclic skeleton include dicyclopentanyl (meth)acrylate, cyclohexyl (meth)acrylate, and isobornyl (meth)acrylate.

Examples of an aliphatic ring included in the constitutional unit having an aliphatic cyclic skeleton include a cyclohexane ring, an isophorone ring, and a tricyclodecane ring.

Among these, a tricyclodecane ring is particularly preferable as the aliphatic ring included in the constitutional unit having an aliphatic cyclic skeleton.

In a case where the binder polymer includes the constitutional unit having an aliphatic cyclic skeleton, the content of the constitutional unit having an aliphatic cyclic skeleton is preferably 5% by mass to 90% by mass, more preferably 10% by mass to 80% by mass, and still more preferably 20% by mass to 70% by mass with respect to the total mass of the binder polymer.

In addition, from the viewpoint of tackiness of the photosensitive layer and hardness after curing, the binder polymer (particularly, the specific polymer A) preferably has a reactive group.

As the reactive group, a radically polymerizable group is preferable, and an ethylenically unsaturated group is more preferable. In addition, in a case where the binder polymer (particularly, the specific polymer A) has an ethylenically unsaturated group, the binder polymer (particularly, the specific polymer A) preferably includes a constitutional unit having an ethylenically unsaturated group in the side chain.

In the present disclosure, the “main chain” represents a relatively longest binding chain in a molecule of a polymer compound constituting a resin, and the “side chain” represents an atomic group branched from the main chain.

The ethylenically unsaturated group is preferably a (meth)acryloyl group and more preferably a (meth)acryloxy group.

In a case where the binder polymer includes the constitutional unit having an ethylenically unsaturated group, the content of the constitutional unit having an ethylenically unsaturated group is preferably 5% by mass to 70% by mass, more preferably 10% by mass to 50% by mass, and still more preferably 20% by mass to 40% by mass with respect to the total mass of the binder polymer.

Examples of a method for introducing the reactive group into the specific polymer A include a method of reacting an epoxy compound, a blocked isocyanate compound, an isocyanate compound, a vinyl sulfone compound, an aldehyde compound, a methylol compound, a carboxylic acid anhydride, or the like with a hydroxy group, a carboxy group, a primary amino group, a secondary amino group, an acetoacetyl group, a sulfo group, or the like.

Preferred examples of the method for introducing the reactive group into the specific polymer A include a method in which a polymer having a carboxy group is synthesized by a polymerization reaction, and then a glycidyl (meth)acrylate is reacted with a part of the carboxy group of the obtained polymer by a polymer reaction, thereby introducing a (meth)acryloxy group into the polymer. By this method, a binder polymer having a (meth)acryloxy group in the side chain (for example, a compound A and compound B shown below) can be obtained.

The above-described polymerization reaction is preferably carried out under a temperature condition of 70° C. to 100° C., and more preferably carried out under a temperature condition of 80° C. to 90° C. As a polymerization initiator used in the above-described polymerization reaction, an azo-based initiator is preferable, and for example, V-601 (product name) or V-65 (product name) manufactured by FUJIFILM Wako Pure Chemical Corporation is more preferable. The above-described polymer reaction is preferably carried out under a temperature condition of 80° C. to 110° C. In the above-described polymer reaction, it is preferable to use a catalyst such as an ammonium salt.

As the specific polymer A, the following compounds A and B are preferable, and a compound B is more preferable. The content ratio of each constitutional unit shown below can be appropriately changed according to the purpose.

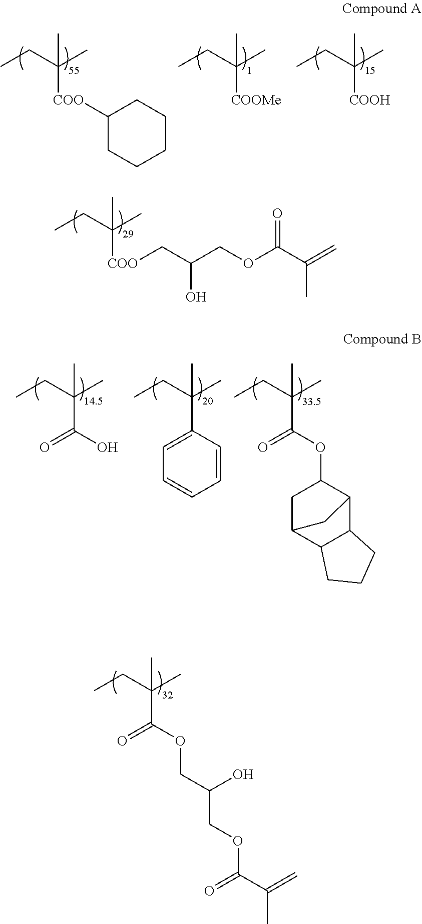

The weight-average molecular weight (Mw) of the specific polymer A is preferably 10,000 or more, more preferably 10,000 to 100,000, and still more preferably 15,000 to 50,000.

The acid value of the binder polymer is preferably 60 mgKOH/g to 200 mgKOH/g, more preferably 60 mgKOH/g to 150 mgKOH/g, and still more preferably 60 mgKOH/g to 110 mgKOH/g.

The acid value of the binder polymer is a value measured according to the method described in JIS K0070: 1992.

In a case where the photosensitive layer includes, as the binder polymer, a binder polymer (particularly, the specific polymer A) having an acid value of 60 mgKOH/g or more, the following advantages can be obtained in addition to the above-mentioned advantages. That is, in a case where a second resin layer which will be described later includes a (meth)acrylic resin having an acid group, it is possible to increase interlaminar adhesion between the photosensitive layer and the second resin layer.

The photosensitive layer may contain, as the binder polymer, a polymer (hereinafter, also referred to as a “polymer B”) including a constitutional unit having a carboxylic acid anhydride structure. In a case where the photosensitive layer contains the specific polymer B, developability of the photosensitive layer and hardness after curing can be improved.

The carboxylic acid anhydride structure may be either a chain carboxylic acid anhydride structure or a cyclic carboxylic acid anhydride structure, and a cyclic carboxylic acid anhydride structure is preferable.

The ring of the cyclic carboxylic acid anhydride structure is preferably a 5- to 7-membered ring, more preferably a 5-membered ring or a 6-membered ring, and particularly preferably a 5-membered ring.

The constitutional unit having a carboxylic acid anhydride structure is preferably a constitutional unit containing a divalent group obtained by removing two hydrogen atoms from a compound represented by Formula P-1 in a main chain, or a constitutional unit in which a monovalent group obtained by removing one hydrogen atom from a compound represented by Formula P-1 is bonded to the main chain directly or through a divalent linking group.

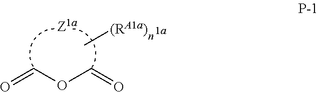

In Formula P-1, R^{A1a} represents a substituent, n^{1a} pieces of R^{A1a}'s may be the same or different, Z^{1a} represents a divalent group forming a ring including —C(═O)—O—C(═O)—, and n^{1a} represents an integer of 0 or more.

Examples of the substituent represented by R^{A1a} include an alkyl group.

Z^{1a} is preferably an alkylene group having 2 to 4 carbon atoms, more preferably an alkylene group having 2 or 3 carbon atoms, and particularly preferably an alkylene group having 2 carbon atoms.

n^{1a} represents an integer of 0 or more. In a case where Z^{1a} represents an alkylene group having 2 to 4 carbon atoms, n^{1a} is preferably an integer of 0 to 4, more preferably an integer of 0 to 2, and particularly preferably 0.

In a case where n^{1a} represents an integer of 2 or more, a plurality of R^{A1a}'s existing may be the same or different. In addition, the plurality of R^{A1a}'s existing may be bonded to each other to form a ring, but it is preferable that they are not bonded to each other to form a ring.

The constitutional unit having a carboxylic acid anhydride structure is preferably a constitutional unit derived from an unsaturated carboxylic acid anhydride, more preferably a constitutional unit derived from an unsaturated cyclic carboxylic acid anhydride, still more preferably a constitutional unit derived from an unsaturated aliphatic carboxylic acid anhydride, particularly preferably a constitutional unit derived from maleic anhydride or itaconic anhydride, and most preferably a constitutional unit derived from maleic acid anhydride.

Hereinafter, specific examples of the constitutional unit having a carboxylic acid anhydride structure will be described, but the constitutional unit having a carboxylic acid anhydride structure is not limited to these specific examples. In the following constitutional units, Rx represents a hydrogen atom, a methyl group, a CH₂OH group, or a CF₃ group, and Me represents a methyl group.

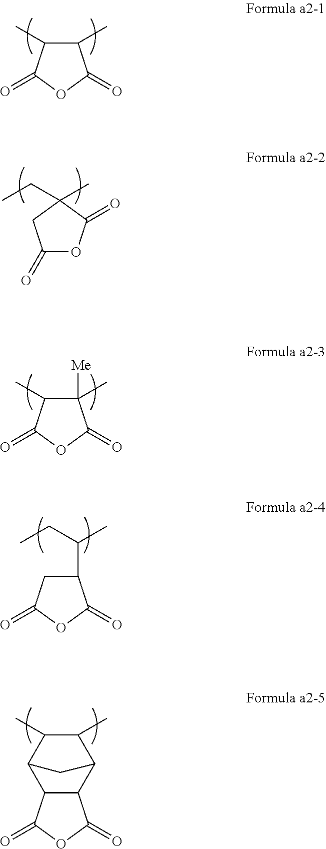

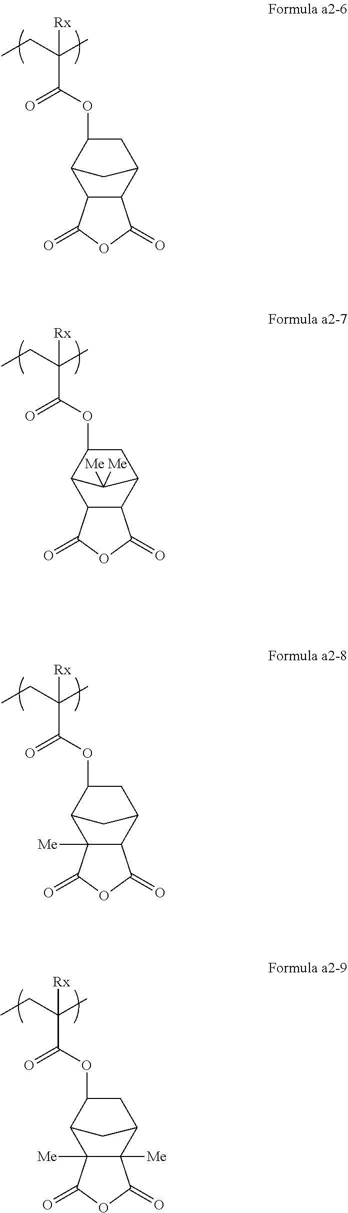

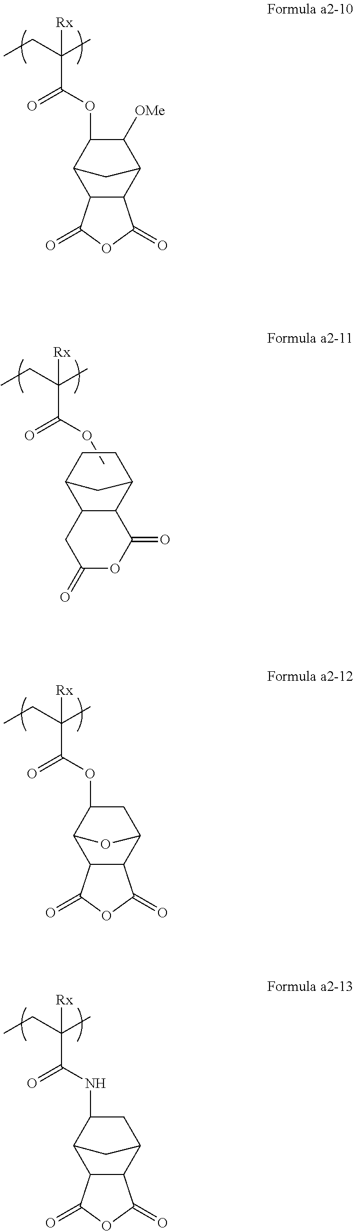

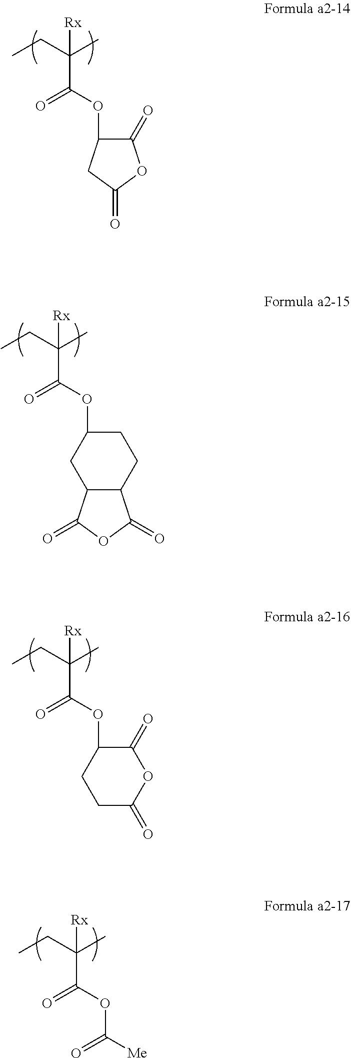

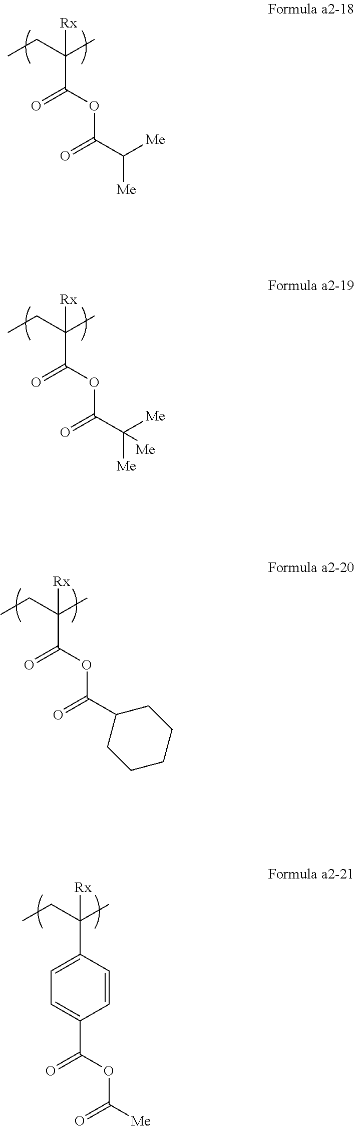

The polymer B may have one constitutional unit having a carboxylic acid anhydride structure alone, or two or more kinds thereof.

The total content of the constitutional unit having a carboxylic acid anhydride structure is preferably 0 mol % to 60 mol %, more preferably 5 mol % to 40 mol %, and particularly preferably 10 mol % to 35 mol % with respect to the total amount of the polymer B.

The weight-average molecular weight (Mw) of the binder polymer is not particularly limited, but is preferably more than 3,000, more preferably more than 3,000 and 60,000 or more, and still more preferably 5,000 to 50,000.

From the viewpoint of patterning properties and reliability, the total content of residual monomers in which each monomer for forming each constitutional unit of the binder polymer remains is preferably 5,000 ppm by mass or less, more preferably 2,000 ppm by mass or less, and still more preferably 500 ppm by mass or less with respect to the total mass of the binder polymer. The lower limit of the total content of the residual monomers is not particularly limited, but the total content of the residual monomers may be 1 ppm by mass or more, or may be 10 ppm by mass or more.

From the viewpoint of patterning properties and reliability, the total content of residual monomers in which each monomer for forming each constitutional unit of the binder polymer remains is preferably 3,000 ppm by mass or less, more preferably 600 ppm by mass or less, and still more preferably 100 ppm by mass or less with respect to the total mass of the photosensitive layer. The lower limit of the total content of the residual monomers is not particularly limited, but the total content of the residual monomers may be 0.1 ppm by mass or more, or may be 1 ppm by mass or more.

Similarly, the residual amount in a case where the compound used for synthesizing the binder polymer in the polymer reaction remains is preferably within the above-described range. For example, in a case where glycidyl acrylate is reacted with a carboxylic acid side chain of a polymer having a carboxylic acid side chain to synthesize the binder polymer, it is preferable that the amount of glycidyl acrylate which is present together with the synthesized binder polymer is within the above-described range.

The above-described amount of residual monomers and the amount of residual compounds can be measured by a known method such as liquid chromatography and gas chromatography.

The photosensitive layer may include only one kind of the binder polymer, or may include two or more kinds thereof.

From the viewpoint of hardness of the cured film and handleability of the transfer film, for example, the content of the binder polymer in the photosensitive layer is preferably 10% by mass to 90% by mass, more preferably 20% by mass to 80% by mass, and still more preferably 30% by mass to 70% by mass with respect to the total mass of the photosensitive layer.

<<Polymerizable Compound>>

From the viewpoint of photosensitivity and hardness of a cured resin layer to be obtained, the photosensitive layer preferably contains a polymerizable compound.

Examples of the polymerizable compound include an ethylenically unsaturated compound, an epoxy compound, and an oxetane compound. Among these, from the viewpoint of photosensitivity and hardness of a cured resin layer to be obtained, an ethylenically unsaturated compound is preferable.

The ethylenically unsaturated compound preferably includes a bi- or higher functional ethylenically unsaturated compound.

In the present disclosure, the “bi- or higher functional ethylenically unsaturated compound” means a compound having two or more ethylenically unsaturated groups in one molecule.

As the ethylenically unsaturated group, a (meth)acryloyl group is preferable.

As the ethylenically unsaturated compound, a (meth)acrylate compound is preferable.

From the viewpoint of hardness of the cured film after curing the photosensitive layer, for example, the ethylenically unsaturated compound particularly preferably includes a bifunctional ethylenically unsaturated compound (preferably, a bifunctional (meth)acrylate compound) and a tri- or higher functional ethylenically unsaturated compound (preferably, a tri- or higher functional (meth)acrylate compound).

The bifunctional ethylenically unsaturated compound is not particularly limited and can be appropriately selected from a known compound.

Examples of the bifunctional ethylenically unsaturated compound include tricyclodecane dimethanol di(meth)acrylate, tricyclodecane dimethanol di(meth)acrylate, 1,9-nonanediol di(meth)acrylate, and 1,6-hexanediol di(meth)acrylate.

Examples of a commercially available product of the bifunctional ethylenically unsaturated compound include tricyclodecane dimethanol diacrylate (product name: NK ESTER A-DCP, manufactured by Shin-Nakamura Chemical Co., Ltd.), tricyclodecane dimethanol dimethacrylate (product name: NK ESTER DCP, manufactured by Shin-Nakamura Chemical Co., Ltd.), 1,10-decanediol diacrylate (product name: NK ESTER A-DOD-N, manufactured by Shin-Nakamura Chemical Co., Ltd.), 1,9-nonanediol diacrylate (product name: NK ESTER A-NOD-N, manufactured by Shin-Nakamura Chemical Co., Ltd.), and 1,6-hexanediol diacrylate (product name: NK ESTER A-HD-N, manufactured by Shin-Nakamura Chemical Co., Ltd.).

The tri- or higher functional ethylenically unsaturated compound is not particularly limited and can be appropriately selected from a known compound.

Examples of the tri- or higher functional ethylenically unsaturated compound include dipentaerythritol (tri/tetra/penta/hexa) (meth)acrylate, pentaerythritol (tri/tetra) (meth)acrylate, trimethylolpropane tri(meth)acrylate, ditrimethylolpropane tetra(meth)acrylate, isocyanuric acid (meth)acrylate, and a (meth)acrylate compound of a glycerin tri(meth)acrylate skeleton.

Here, the “(tri/tetra/penta/hexa) (meth)acrylate” has a concept including tri(meth)acrylate, tetra(meth)acrylate, penta(meth)acrylate, and hexa(meth)acrylate, and the “(tri/tetra) (meth)acrylate” has a concept including tri(meth)acrylate and tetra(meth)acrylate.

Examples of the ethylenically unsaturated compound also include a caprolactone-modified compound of a (meth)acrylate compound (KAYARAD (registered trademark) DPCA-20 manufactured by Nippon Kayaku Co., Ltd., A-9300-1CL manufactured by Shin-Nakamura Chemical Co., Ltd., or the like), a mixture of dipentaerythritol hexaacrylate/dipentaerythritol pentaacrylate (KAYARAD DPHA76 manufactured by Nippon Kayaku Co., Ltd., or the like), an alkylene oxide-modified compound of a (meth)acrylate compound (KAYARAD (registered trademark) RP-1040 manufactured by Nippon Kayaku Co., Ltd., ATM-35E or A-9300 manufactured by Shin-Nakamura Chemical Co., Ltd., EBECRYL (registered trademark) 135 manufactured by Daicel-Allnex Ltd., or the like), and ethoxylated glycerin triacrylate (NK ESTER A-GLY-9E manufactured by Shin-Nakamura Chemical Co., Ltd., or the like).

Examples of the ethylenically unsaturated compound also include a urethane (meth)acrylate compound.

Examples of urethane (meth)acrylate include urethane di(meth)acrylate. Examples thereof include a propylene oxide-modified urethane di(meth)acrylate and urethane di(meth)acrylate modified with both ethylene oxide and propylene oxide. In addition, examples of urethane (meth)acrylate also include urethane tri- or higher functional (meth)acrylate. As the lower limit value of the number of functional groups (the number of (meth)acrylate groups) in the urethane (meth)acrylate, the urethane (meth)acrylate is more preferably 6—or higher functional, and still more preferably 8—or higher functional. As the upper limit of the number of functional groups of the urethane (meth)acrylate, the urethane (meth)acrylate may be, for example, 20—or lower functional.

Examples of the tri- or higher functional urethane (meth)acrylate include 8UX-015A (manufactured by Taisei Fine Chemical Co., Ltd.), UA-32P (manufactured by Shin-Nakamura Chemical Co., Ltd.), U-15HA (manufactured by Shin-Nakamura Chemical Co., Ltd.), UA-1100H (manufactured by Shin-Nakamura Chemical Co., Ltd.), AH-600 (product name, manufactured by KYOEISHA CHEMICAL Co., LTD), UA-306H, UA-306T, UA-306I, UA-510H, and UX-5000 (all manufactured by Nippon Kayaku Co., Ltd.).

From the viewpoint of improving developability, the ethylenically unsaturated compound preferably includes an ethylenically unsaturated compound having an acid group.

Examples of the acid group include a phosphoric acid group, a sulfo group, and a carboxy group.

Among these, as the acid group, a carboxy group is preferable.

Examples of the ethylenically unsaturated compound having an acid group include a tri- or tetra-functional ethylenically unsaturated compound having an acid group [component obtained by introducing a carboxy group to pentaerythritol tri- and tetra-acrylate (PETA) skeleton (acid value: 80 mgKOH/g to 120 mgKOH/g)), and a penta- to hexa-functional ethylenically unsaturated compound having an acid group [component obtained by introducing a carboxy group to dipentaerythritol penta- and hexa-acrylate (DPHA) skeleton (acid value: 25 mgKOH/g to 70 mgKOH/g)].

The tri- or higher functional ethylenically unsaturated compound having an acid group may be used in combination with the bifunctional ethylenically unsaturated compound having an acid group, as necessary.

As the ethylenically unsaturated compound having an acid group, at least one selected from the group consisting of bi- or higher functional ethylenically unsaturated compound having a carboxy group and a carboxylic acid anhydride thereof is preferable.

In a case where the ethylenically unsaturated compound having an acid group is at least one selected from the group consisting of bi- or higher functional ethylenically unsaturated compound having a carboxy group and a carboxylic acid anhydride thereof, developability of the photosensitive layer and film hardness is further enhanced.

The bi- or higher functional ethylenically unsaturated compound having a carboxy group is not particularly limited and can be appropriately selected from a known compound.

As the bi- or higher functional ethylenically unsaturated compound having a carboxy group, ARONIX (registered trademark) TO-2349 (manufactured by Toagosei Co., Ltd.), ARONIX (registered trademark) M-520 (manufactured by Toagosei Co., Ltd.), ARONIX (registered trademark) M-510 (manufactured by Toagosei Co., Ltd.), or the like can be preferably used.

As the ethylenically unsaturated compound having an acid group, polymerizable compounds having an acid group, which are described in paragraphs 0025 to 0030 of JP2004-239942A, can be preferably used, and the contents described in this publication are incorporated in the present disclosure.

The photosensitive layer may contain one ethylenically unsaturated compound having an acid group alone, or two or more kinds thereof.

From the viewpoint of developability of the photosensitive layer, and pressure-sensitive adhesiveness of an uncured film to be obtained, the content of the ethylenically unsaturated compound having an acid group is preferably 0.1% by mass to 30% by mass, more preferably 0.5% by mass to 20% by mass, still more preferably 1% by mass to 10% by mass, and particularly preferably 1% by mass to 5% by mass with respect to the total mass of the photosensitive layer.

Among these, from the viewpoint of film hardness of the photosensitive layer, curing property, and suppressing resistance change of the silver conductive material after the wet heat test or the heat test, the polymerizable compound included in the photosensitive layer preferably includes two or more kinds of polyfunctional (meth)acrylate compounds, more preferably includes 3 to 10 kinds of polyfunctional (meth)acrylate compounds, and still more preferably includes a bifunctional (meth)acrylate compound, a trifunctional (meth)acrylate compound, and a tetrafunctional (meth)acrylate compound. In addition, the polymerizable compound also still more preferably includes a bifunctional (meth)acrylate compound, a trifunctional (meth)acrylate compound, a tetrafunctional (meth)acrylate compound, and a urethane (meth)acrylate compound.

In addition, more specifically, from the viewpoint of film hardness of the photosensitive layer, curing property, and suppressing resistance change of the silver conductive material after the wet heat test or the heat test, the polymerizable compound included in the photosensitive layer preferably includes an alcanediol di(meth)acrylate compound, a trifunctional (meth)acrylate compound, and a tetrafunctional (meth)acrylate compound, and more preferably includes 1,9-nonanediol di(meth)acrylate or 1,10-decanediol di(meth)acrylate, pentaerythritol tri(meth)acrylate, and pentaerythritol tetra(meth)acrylate. In addition, the polymerizable compound also more preferably includes 1,9-nonanediol di(meth)acrylate or 1,10-decanediol di(meth)acrylate, pentaerythritol tri(meth)acrylate, pentaerythritol tetra(meth)acrylate, and a urethane (meth)acrylate compound.

In addition, as the polymerizable compound included in the photosensitive layer, the following aspects are also preferably mentioned.

From the viewpoint of film hardness of the photosensitive layer, curing property, and suppressing resistance change of the silver conductive material after the wet heat test or the heat test, the polymerizable compound included in the photosensitive layer preferably includes a bifunctional (meth)acrylate compound, a pentafunctional (meth)acrylate compound, and a hexafunctional (meth)acrylate compound. In addition, the polymerizable compound also preferably includes a bifunctional (meth)acrylate compound, a pentafunctional (meth)acrylate compound, a hexafunctional (meth)acrylate compound, and a urethane (meth)acrylate compound.

Further, specifically, from the viewpoint of film hardness of the photosensitive layer, curing property, and suppressing resistance change of the silver conductive material after the wet heat test or the heat test, the polymerizable compound included in the photosensitive layer preferably includes an alcanediol di(meth)acrylate compound, a pentafunctional (meth)acrylate compound, and a hexafunctional (meth)acrylate compound, and more preferably includes 1,9-nonanediol di(meth)acrylate or 1,10-decanediol di(meth)acrylate, dipentaerythritol hexa(meth)acrylate, and dipentaerythritol penta(meth)acrylate. In addition, the polymerizable compound also more preferably includes 1,9-nonanediol di(meth)acrylate or 1,10-decanediol di(meth)acrylate, dipentaerythritol hexa(meth)acrylate, dipentaerythritol penta(meth)acrylate, and a urethane (meth)acrylate compound.

The molecular weight of the polymerizable compound is preferably 200 to 3,000, more preferably 250 to 2,600, still more preferably 280 to 2,200, and particularly preferably 300 to 2,200.

The proportion of the content of the polymerizable compound having a molecular weight of 300 or less in the polymerizable compounds included in the photosensitive layer is preferably 30% by mass or less, more preferably 25% by mass or less, and still more preferably 20% by mass or less with respect to the content of all the polymerizable compounds included in the photosensitive layer.

The photosensitive layer may include only one kind of the polymerizable compound, or may include two or more kinds thereof.

The content of the polymerizable compound is preferably 1% by mass to 70% by mass, more preferably 10% by mass to 70% by mass, still more preferably 20% by mass to 60% by mass, and particularly preferably 20% by mass to 50% by mass with respect to the total mass of the photosensitive layer.

In a case where the photosensitive layer includes a bifunctional ethylenically unsaturated compound and a tri- or higher functional ethylenically unsaturated compound, the content of the bifunctional ethylenically unsaturated compound is preferably 10% by mass to 90% by mass, more preferably 20% by mass to 85% by mass, and still more preferably 30% by mass to 80% by mass with respect to the total content of all the ethylenically unsaturated compounds included in the photosensitive layer.

In this case, the content of the trifunctional ethylenically unsaturated compound is preferably 10% by mass to 90% by mass, more preferably 15% by mass to 80% by mass, and still more preferably 20% by mass to 70% by mass with respect to the total content of all the ethylenically unsaturated compounds included in the photosensitive layer.

In addition, in this case, the content of the bi- or higher functional ethylenically unsaturated compound is preferably 40% by mass or more and less than 100% by mass, more preferably 40% by mass to 90% by mass, still more preferably 50% by mass to 80% by mass, and particularly preferably 50% by mass to 70% by mass with respect to a total content of the bifunctional ethylenically unsaturated compound and the tri- or higher functional ethylenically unsaturated compound.

In a case of including the bi- or higher functional polymerizable compound, the photosensitive layer may further include a monofunctional polymerizable compound.

In a case where the photosensitive layer includes the bi- or higher functional polymerizable compound, the bi- or higher functional polymerizable compound is preferably a main component of the polymerizable compound included in the photosensitive layer.

In a case where the photosensitive layer includes the bi- or higher functional polymerizable compound, the content of the bi- or higher functional polymerizable compound is preferably 60% by mass to 100% by mass, more preferably 80% by mass to 100% by mass, and particularly preferably 90% by mass to 100% by mass with respect to the total content of all the polymerizable compounds included in the photosensitive layer.

In a case where the photosensitive layer includes the ethylenically unsaturated compound having an acid group (preferably, bi- or higher functional ethylenically unsaturated compound including a carboxy group or a carboxylic acid anhydride thereof), the content of the ethylenically unsaturated compound having an acid group is preferably 1% by mass to 50% by mass, more preferably 1% by mass to 20% by mass, and still more preferably 1% by mass to 10% by mass with respect to the total mass of the photosensitive layer.

<<Photopolymerization Initiator>>

The photosensitive layer contains a photopolymerization initiator.

The photopolymerization initiator is not particularly limited and a known photopolymerization initiator can be used.

The photopolymerization initiator may be a radical polymerization initiator or a cationic polymerization initiator, but a radical polymerization initiator is preferable.

Examples of the photopolymerization initiator include a photopolymerization initiator having an oxime ester structure (hereinafter, also referred to as an “oxime-based photopolymerization initiator”), a photopolymerization initiator having an α-aminoalkylphenone structure (hereinafter, also referred to as an “α-aminoalkylphenone-based photopolymerization initiator”), a photopolymerization initiator having an α-hydroxyalkylphenone structure (hereinafter also referred to as an “α-hydroxyalkylphenone-based photopolymerization initiator”), a photopolymerization initiator having an acylphosphine oxide structure, (hereinafter, also referred to as an “acylphosphine oxide-based photopolymerization initiator”), and a photopolymerization initiator having an N-phenylglycine structure (hereinafter, also referred to as an N-phenylglycine-based photopolymerization initiator”).

The photopolymerization initiator preferably includes at least one kind selected from the group consisting of the oxime-based photopolymerization initiator, the α-aminoalkylphenone-based photopolymerization initiator, the α-hydroxyalkylphenone-based photopolymerization initiator, and the N-phenylglycine-based photopolymerization initiator, and more preferably includes at least one kind selected from the group consisting of the oxime-based photopolymerization initiator, the α-aminoalkylphenone-based photopolymerization initiator, and the N-phenylglycine-based photopolymerization initiator.

In addition, as the photopolymerization initiator, for example, polymerization initiators disclosed in paragraphs 0031 to 0042 of JP2011-95716A and paragraphs 0064 to 0081 of JP2015-014783A may be used.

Examples of a commercially available product of the photopolymerization initiator include 1-[4-(phenylthio)phenyl]-1,2-octanedione-2-(O-benzoyloxime) [product name: IRGACURE (registered trademark) OXE-01, manufactured by BASF SE], 1-[9-ethyl-6-(2-methylbenzoyl)-9H-carbazol-3-yl]ethanone-1-(O-acetyloxime) [product name: IRGACURE (registered trademark) OXE-02, manufactured by BASF SE], [8-[5-(2,4,6-trimethylphenyl)-11-(2-ethylhexyl)-11H-benzo[a]carbazoyl][2-(2,2,3,3-tetrafluoro propoxy)phenyl]methanone-(O-acetyloxime) [product name: IRGACURE (registered trademark) OXE-03, manufactured by BASF SE], 1-[4-[4-(2-benzofuranylcarbonyl)phenyl]thio]phenyl]-4-methyl-1-pentanone-1-(O-acetyloxime) [product name: IRGACURE (registered trademark) OXE-04, manufactured by BASF SE], 2-(dimethylamino)-2-[(4-methylphenyl)methyl]-1-[4-(4-morpholinyl)phenyl]-1-butanone [product name: IRGACURE (registered trademark) 379EG, manufactured by BASF SE], 2-methyl-1-(4-methylthiophenyl)-2-morpholinopropan-1-one [product name: IRGACURE (registered trademark) 907, manufactured by BASF SE], 2-hydroxy-1-{4-[4-(2-hydroxy-2-methylpropionyl)benzyl]phenyl}-2-methylpropan-1-one [product name: IRGACURE (registered trademark) 127, manufactured by BASF SE], 2-benzyl-2-dimethylamino-1-(4-morpholinophenyl)butanone-1 [product name: IRGACURE (registered trademark) 369, manufactured by BASF SE], 2-hydroxy-2-methyl-1-phenylpropan-1-one [product name: IRGACURE (registered trademark) 1173, manufactured by BASF SE], 1-hydroxy cyclohexyl phenyl ketone [product name: IRGACURE (registered trademark) 184, manufactured by BASF SE], 2,2-dimethoxy-1,2-diphenylethan-1-one (product name: IRGACURE (registered trademark) 651, manufactured by BASF SE], and an oxime ester-based product [product name: Lunar 6, manufactured by DKSH Management Ltd.].

The photosensitive layer may include only one kind of the photopolymerization initiator, or may include two or more kinds thereof.

The content of the photopolymerization initiator is not particularly limited, but is preferably 0.1% by mass or more, more preferably 0.5% by mass or more, and still more preferably 1.0% by mass or more with respect to the total mass of the photosensitive layer.

In addition, the content of the photopolymerization initiator is preferably 10% by mass or less and more preferably 5% by mass or less with respect to the total mass of the photosensitive layer.

<<Heterocyclic Compound>>

It is preferable that the photosensitive layer further contains a heterocyclic compound. The heterocyclic compound contributes to the improvement of adhesiveness to the silver conductive material and corrosion inhibitory property of the silver conductive material.

A heterocyclic ring included in the heterocyclic compound may be either a monocyclic or polycyclic heterocyclic ring.

Examples of a heteroatom included in the heterocyclic compound include an oxygen atom, a nitrogen atom, and a sulfur atom. The heterocyclic compound preferably has at least one atom selected from the group consisting of a nitrogen atom, an oxygen atom, and a sulfur atom, and more preferably has a nitrogen atom.

Preferred examples of the heterocyclic compound include a triazole compound, a benzotriazole compound, a tetrazole compound, a thiadiazole compound, a triazine compound, a rhodanine compound, a thiazole compound, a benzothiazole compound, a benzimidazole compound, a benzoxazole compound, and a pyrimidine compound. Among the above, the heterocyclic compound is preferably at least one compound selected from the group consisting of a triazole compound, a benzotriazole compound, a tetrazole compound, a thiadiazole compound, a triazine compound, a rhodanine compound, a thiazole compound, a benzimidazole compounds, and a benzoxazole compound, and more preferably at least one compound selected from the group consisting of a triazole compound, a benzotriazole compound, a tetrazole compound, a thiadiazole compound, a thiazole compound, a benzothiazole compound, a benzimidazole compound, and a benzoxazole compound.

Preferred specific examples of the heterocyclic compound are shown below. Examples of the triazole compound and the benzotriazole compound include the following compounds.

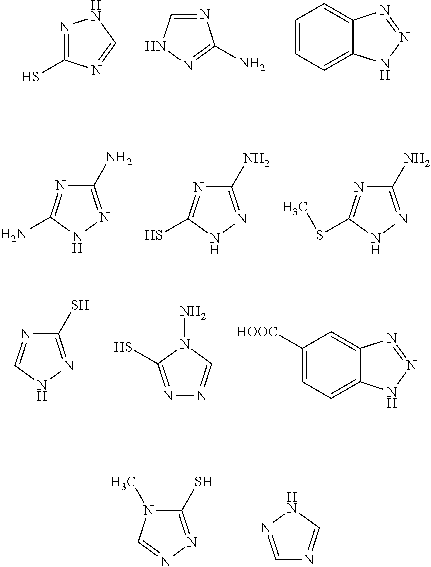

Examples of the tetrazole compound include the following compounds.

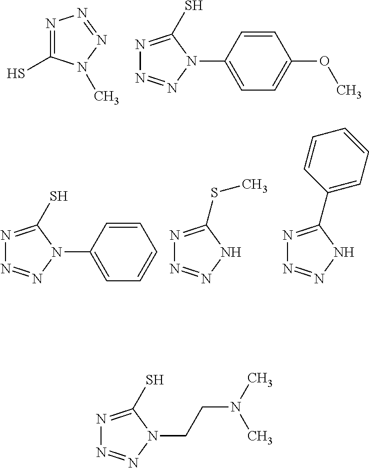

Examples of the thiadiazole compound include the following compounds.

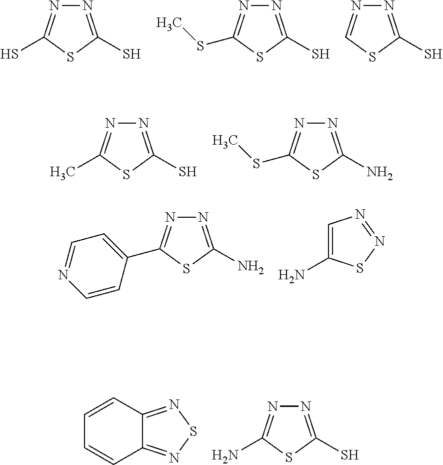

Examples of the triazine compound include the following compounds.

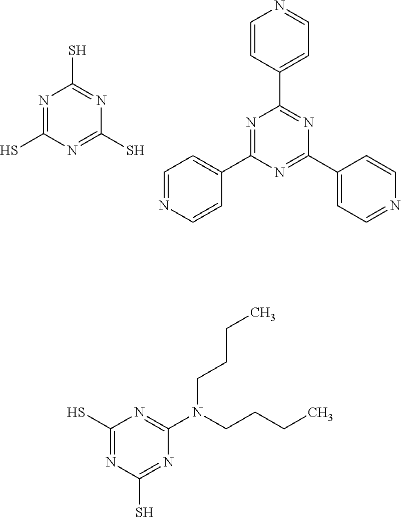

Examples of the rhodanine compound include the following compounds.

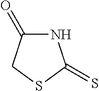

Examples of the thiazole compound include the following compounds.

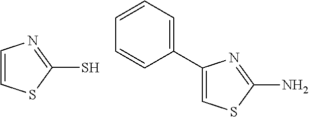

Examples of the benzothiazole compound include the following compounds.

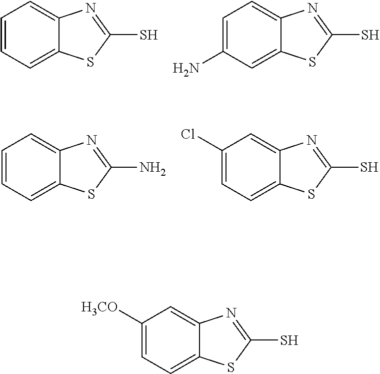 [SMILES: Sc1nc2ccccc2s1 ; Nc1ccc2nc(S)sc2c1 ; Nc1nc2ccccc2s1 ; Sc1nc2cc(Cl)ccc2s1 ; COc1ccc2sc(S)nc2c1]

Examples of the benzimidazole compound include the following compounds.

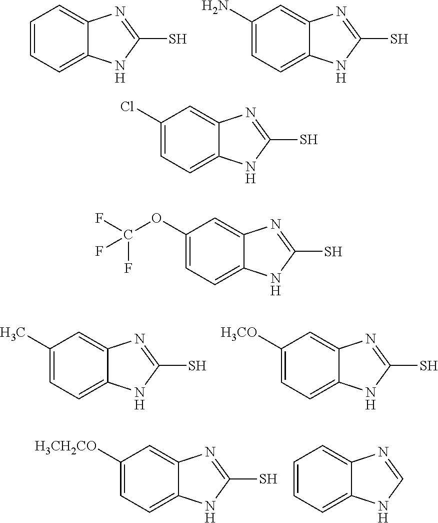

Examples of the benzoxazole compound include the following compounds.

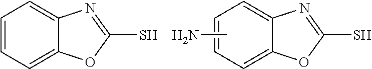

The photosensitive layer may include only one kind of the heterocyclic compound, or may include two or more kinds thereof.

The content of the heterocyclic compound is preferably 0.01% by mass to 20% by mass, more preferably 0.1% by mass to 10% by mass, still more preferably 0.3% by mass to 8% by mass, and particularly preferably 0.5% by mass to 5% by mass with respect to the total mass of the photosensitive layer. In a case where the content of the heterocyclic compound is within the above-described range, the adhesiveness to the silver conductive material and the corrosion inhibitory property of the silver conductive material can be improved.

<<Aliphatic Thiol Compound>>

It is preferable that the photosensitive layer includes an aliphatic thiol compound.

In a case where the photosensitive layer includes an aliphatic thiol compound, the ene-thiol reaction of the aliphatic thiol compound suppresses a curing contraction of the formed film and relieves stress. Therefore, adhesiveness of the formed cured film to the silver conductive material (particularly, adhesiveness after exposure) tends to be improved.

In general, in a case where the photosensitive layer includes an aliphatic thiol compound, the silver conductive material is more easily corroded. On the other hand, the photosensitive layer in the present disclosure has an advantage that a cured film having excellent corrosion inhibitory property of the silver conductive material can be formed even in a case where the photosensitive layer in the present disclosure includes an aliphatic thiol compound.

As the aliphatic thiol compound, a monofunctional aliphatic thiol compound or a polyfunctional aliphatic thiol compound (that is, bi- or higher functional aliphatic thiol compound) is suitably used.

Among these, for example, from the viewpoint of adhesiveness of the formed cured film to the substrate (particularly, adhesiveness after exposure), the aliphatic thiol compound preferably includes a polyfunctional aliphatic thiol compound, and is more preferably a polyfunctional aliphatic thiol compound.

In the present disclosure, the “polyfunctional aliphatic thiol compound” refers to an aliphatic compound having two or more thiol groups (also referred to as “mercapto groups”) in a molecule.

The polyfunctional aliphatic thiol compound is preferably a low-molecular-weight compound having a molecular weight of 100 or more. Specifically, the molecular weight of the polyfunctional aliphatic thiol compound is more preferably 100 to 1,500 and still more preferably 150 to 1,000.

From the viewpoint of adhesiveness of the formed cured film to the substrate, for example, the number of functional groups of the polyfunctional aliphatic thiol compound is preferably 2 to 10, more preferably 2 to 8, and still more preferably 2 to 6.

Examples of the polyfunctional aliphatic thiol compound include trimethylolpropane tris(3-mercaptobutyrate), 1,4-bis(3-mercaptobutyryloxy)butane, pentaerythritol tetrakis(3-mercaptobutyrate), 1,3,5-tris(3-mercaptobutyryloxyethyl)-1,3,5-triazine-2,4,6(1H,3H,5H)-trione, trimethylolethane tris(3-mercaptobutyrate), tris[(3-mercaptopropionyloxy)ethyl] isocyanurate, trimethylolpropane tris(3-mercaptopropionate), pentaerythritol tetrakis(3-mercaptopropionate), tetraethylene glycol bis(3-mercaptopropionate), dipentaerythritol hexakis(3-mercaptopropionate), ethylene glycol bisthiopropionate, 1,2-ethanedithiol, 1,3-propanedithiol, 1,6-hexamethylenedithiol, 2,2′-(ethylenedithio)diethanethiol, meso-2,3-dimercaptosuccinic acid, and di(mercaptoethyl) ether.

Among these, the polyfunctional aliphatic thiol compound is preferably at least one selected from the group consisting of trimethylolpropane tris(3-mercaptobutyrate), 1,4-bis(3-mercaptobutyryloxy)butane, and 1,3,5-tris(3-mercaptobutyryloxyethyl)-1,3,5-triazine-2,4,6(1H,3H,5H)-trione.

Examples of the monofunctional aliphatic thiol compound include 1-octanethiol, 1-dodecanethiol, β-mercaptopropionic acid, methyl-3-mercaptopropionate, 2-ethylhexyl-3-mercaptopropionate, n-octyl-3-mercaptopropionate, methoxybutyl-3-mercaptopropionate, and stearyl-3-mercaptopropionate.

The photosensitive layer may include only one kind of the aliphatic thiol compound, or may include two or more kinds thereof.

The content of the aliphatic thiol compound is preferably 5% by mass or more, more preferably 5% by mass to 50% by mass, still more preferably 5% by mass to 30% by mass, and particularly preferably 8% by mass to 20% by mass with respect to the total mass of the photosensitive layer.

In a case where the content of the aliphatic thiol compound is 5% by mass or more with respect to the total mass of the photosensitive layer, a cured film having more excellent adhesiveness (particularly, adhesiveness after exposure) of the photosensitive layer to the silver conductive material tends to be formed.

<<Thermal Crosslinking Compound>>

From the viewpoint of hardness of a cured film to be obtained and pressure-sensitive adhesiveness of an uncured film to be obtained, it is preferable that the photosensitive layer contains a thermal crosslinking compound.

Examples of the thermal crosslinking compound include an epoxy compound, an oxetane compound, a methylol compound, and a blocked isocyanate compound. Among these, from the viewpoint of hardness of a cured film to be obtained and pressure-sensitive adhesiveness of an uncured film to be obtained, a blocked isocyanate compound is preferable.

In the present disclosure, in a case where the photosensitive layer includes only a radical polymerization initiator as the photopolymerization initiator, the above-described epoxy compound and the above-described oxetane compound are treated as the thermal crosslinking compound, and in a case of including a cationic polymerization initiator, the above-described epoxy compound and the above-described oxetane compound are treated as the polymerizable compound.

Since the blocked isocyanate compound reacts with a hydroxy group and a carboxy group, for example, in a case where at least one of the binder polymer or the radically polymerizable compound having an ethylenically unsaturated group has at least one of a hydroxy group or a carboxy group, hydrophilicity of the formed film tends to decrease, and the function as a protective film tends to be strengthened.

The blocked isocyanate compound refers to a “compound having a structure in which the isocyanate group of isocyanate is protected (so-called masked) with a blocking agent”.

The dissociation temperature of the blocked isocyanate compound is not particularly limited, but is preferably 100° C. to 160° C. and more preferably 130° C. to 150° C.

The dissociation temperature of blocked isocyanate in the present disclosure means “temperature at an endothermic peak accompanied with a deprotection reaction of blocked isocyanate, in a case where the measurement is performed by differential scanning calorimetry (DSC) analysis using a differential scanning calorimeter”.

As the differential scanning calorimeter, for example, a differential scanning calorimeter (model: DSC6200) manufactured by Seiko Instruments Inc. can be suitably used. However, the differential scanning calorimeter is not limited thereto.

Examples of the blocking agent having a dissociation temperature of 100° C. to 160° C. include an active methylene compound [diester malonates (such as dimethyl malonate, diethyl malonate, di-n-butyl malonate, and di-2-ethylhexyl malonate)], and an oxime compound (compound having a structure represented by —C(═N—OH)— in a molecule, such as formaldoxime, acetoaldoxime, acetoxime, methyl ethyl ketoxime, and cyclohexanoneoxime).

Among these, from the viewpoint of storage stability, the blocking agent blocking agent having a dissociation temperature of 100° C. to 160° C. is preferably, for example, at least one selected from oxime compounds.

From the viewpoint of improving brittleness of the film and improving the adhesion to a transferred material, for example, the blocked isocyanate compound preferably has an isocyanurate structure.

The blocked isocyanate compound having an isocyanurate structure can be obtained, for example, by isocyanurate-forming and protecting hexamethylene diisocyanate.

Among the blocked isocyanate compounds having an isocyanurate structure, a compound having an oxime structure using an oxime compound as a blocking agent is preferable from the viewpoint that the dissociation temperature can be easily set in a preferred range and the development residue can be easily reduced, as compared with a compound having no oxime structure.

The blocked isocyanate compound preferably has a polymerizable group and more preferably has a radically polymerizable group, from the viewpoint of hardness of the cured film obtained from the photosensitive layer.

The polymerizable group is not particularly limited, and a known polymerizable group can be used.

Examples of the polymerizable group include a (meth)acryloxy group, a (meth)acrylamide group, an ethylenically unsaturated group such as styryl group, and an epoxy group such as a glycidyl group.

Among these, as the polymerizable group, from the viewpoint of surface shape of the surface of the cured film obtained from the photosensitive layer, a development speed, and reactivity, an ethylenically unsaturated group is preferable, and a (meth)acryloxy group is more preferable.

As the blocked isocyanate compound, a commercially available product can be used.

Examples of the commercially available product of the blocked isocyanate compound include Karenz (registered trademark) AOI-BM, Karenz (registered trademark) MOI-BM, Karenz (registered trademark) MOI-BP, and the like (all manufactured by SHOWA DENKO K.K.), and block-type DURANATE series (for example, DURANATE (registered trademark) TPA-B80E, manufactured by Asahi Kasei Corporation).

The photosensitive layer may include only one kind of the thermal crosslinking compound, or may include two or more kinds thereof.

The content of the thermal crosslinking compound is preferably 1% by mass to 50% by mass and more preferably 5% by mass to 30% by mass with respect to the total mass of the photosensitive layer.

<<Surfactant>>

The photosensitive layer may include a surfactant.

The surfactant is not particularly limited, and a known surfactant can be used.

Examples of the surfactant include surfactants described in paragraph 0017 of JP4502784B and paragraphs 0060 to 0071 of JP2009-237362A.

As the surfactant, a fluorine-based surfactant or a silicon-based surfactant is preferable.

Examples of a commercially available product of the fluorine-based surfactant include MEGAFACE (registered trademark) F551A (manufactured by DIC Corporation) and DOWSIL (registered trademark) 8032 Additive.

The photosensitive layer may include only one kind of the surfactant, or may include two or more kinds thereof.

The content of the surfactant is preferably 0.01% by mass to 3% by mass, more preferably 0.05% by mass to 1% by mass, and still more preferably 0.1% by mass to 0.8% by mass with respect to the total mass of the photosensitive layer.

<<Hydrogen Donating Compound>>

It is preferable that the photosensitive layer includes a hydrogen donating compound.

In the photosensitive layer, the hydrogen donating compound has a function of further improving sensitivity of the photopolymerization initiator to actinic ray, or suppressing inhibition of polymerization of the polymerizable compound by oxygen.

Examples of such a hydrogen donating compound include amines, for example, compounds described in M. R. Sander et al., “Journal of Polymer Society,” Vol. 10, page 3173 (1972), JP1969-20189B (JP-S44-20189B), JP1976-82102A (JP-S51-82102A), JP1977-134692A (JP-S52-134692A), JP1984-138205A (JP-S59-138205A), JP1985-84305A (JP-S60-84305A), JP1987-18537A (JP-S62-18537A), JP1989-33104A (JP-S64-33104A), and Research Disclosure 33825.

Specific examples of the hydrogen donating compound include triethanolamine, p-dimethylaminobenzoic acid ethyl ester, p-formyldimethylaniline, and p-methylthiodimethylaniline.

In addition, examples of the hydrogen donating compound also include an amino acid compound (N-phenylglycine and the like), an organic metal compound described in JP1973-42965B (JP-S48-42965B) (tributyl tin acetate and the like), a hydrogen donor described in JP1980-34414B (JP-S55-34414B), and a sulfur compound described in JP1994-308727A (JP-H06-308727A) (trithiane and the like).

The photosensitive layer may include only one kind of the hydrogen donating compound, or may include two or more kinds thereof.

For example, from the viewpoint of improving a curing rate by balancing the polymerization growth rate and chain transfer, the content of the hydrogen donating compound is preferably 0.01% by mass to 10% by mass, more preferably 0.03% by mass to 5% by mass, and still more preferably 0.05% by mass to 3% by mass with respect to the total mass of the photosensitive layer.

<<Other Components>>

The photosensitive layer may include components (so-called other components) other than the components described above.

Examples of the other components include particles (for example, metal oxide particles) and a colorant.

In addition, examples of the other components include a thermal polymerization inhibitor described in paragraph 0018 of JP4502784B and other additives described in paragraphs 0058 to 0071 of JP2000-310706A.

—Particles—

The photosensitive layer may include particles (for example, metal oxide particles; the same applies hereinafter) for the purpose of adjusting refractive index, light-transmitting property, and the like.

The metal of the metal oxide particles also includes semimetal such as B, Si, Ge, As, Sb, or Te.

From the viewpoint of transparency of the cured film, for example, the average primary particle diameter of the particles is preferably 1 nm to 200 nm and more preferably 3 nm to 80 nm.

The average primary particle diameter of the particles is calculated by measuring particle diameters of 200 random particles using an electron microscope and arithmetically averaging the measurement result. In a case where the shape of the particle is not a spherical shape, the longest side is set as the particle diameter.

In a case where the photosensitive layer includes particles, the photosensitive layer may include only one kind of particles having different metal types, sizes, and the like, or may include two or more kinds thereof.

It is preferable that the photosensitive layer does not include particles, or the content of the particles is more than 0% by mass to 35% by mass or less with respect to the total mass of the photosensitive layer; it is more preferable that the photosensitive layer does not include particles, or the content of the particles is more than 0% by mass to 10% by mass or less with respect to the total mass of the photosensitive layer; it is still more preferable that the photosensitive layer does not include particles, or the content of the particles is more than 0% by mass to 5% by mass or less with respect to the total mass of the photosensitive layer; it is even more preferable that the photosensitive layer does not include particles, or the content of the particles is more than 0% by mass to 1% by mass or less with respect to the total mass of the photosensitive layer; and it is particularly preferable that the photosensitive layer does not include particles.

—Colorant—

The photosensitive layer may include a trace amount of a colorant (pigment, dye, and the like), but for example, from the viewpoint of transparency, it is preferable that the photosensitive layer does not substantially include the colorant.

The content of the colorant is preferably less than 1% by mass and more preferably less than 0.1% by mass with respect to the total mass of the photosensitive layer.

The thickness of the photosensitive layer is not particularly limited, but from the viewpoint of manufacturing suitability, reducing the thickness of the entire transfer film, improvement of the transmittance of the photosensitive layer or a cured film to be obtained, and suppression of yellowing of the photosensitive layer or a cured film to obtained, the thickness of the photosensitive layer is preferably 0.01 μm to 20 μm, more preferably 0.02 μm to 15 μm, still more preferably 0.05 μm to 10 μm, and particularly preferably 1 μm to 10 μm.

The thickness of each layer such as the photosensitive layer is obtained as an average value of 5 random points measured by cross-sectional observation with a scanning electron microscope (SEM).

The refractive index of the photosensitive layer is not particularly limited, but is preferably 1.47 to 1.56, more preferably 1.50 to 1.53, still more preferably 1.50 to 1.52, and particularly preferably 1.51 to 1.52.

A method for forming the photosensitive layer is not particularly limited, and a known method can be used.

As an example of the method for forming the photosensitive layer, a method forming the photosensitive layer by applying a photosensitive composition including a solvent onto a temporary support and then drying, as necessary is used.

As a coating method, a known method can be used.

Examples of the coating method include a printing method, a spray coating method, a roll coating method, a bar coating method, a curtain coating method, a spin coating method, and a die coating method (that is, a slit coating method).

Among these, a die coating method is preferable as the coating method.

As a drying method, known methods such as natural drying, heating drying, and drying under reduced pressure can be used, and these methods can be applied alone or in combination of plural thereof.

In the present disclosure, the “drying” means removing at least a part of the solvent included in the composition.

It is preferable to use a solvent for forming the photosensitive layer. In a case where the above-described photosensitive composition includes a solvent, the formation of the photosensitive layer by coating tends to be easier.

As the solvent, a generally used solvent can be used without particular limitation.

The solvent is preferably an organic solvent.

Examples of the organic solvent include methyl ethyl ketone, propylene glycol monomethyl ether, propylene glycol monomethyl ether acetate (another name: 1-methoxy-2-propyl acetate), diethylene glycol ethyl methyl ether, cyclohexanone, methyl isobutyl ketone, ethyl lactate, methyl lactate, caprolactam, n-propanol, and 2-propanol.

As the solvent, a mixed solvent of methyl ethyl ketone and propylene glycol monomethyl ether acetate or a mixed solvent of diethylene glycol ethyl methyl ether and propylene glycol monomethyl ether acetate is preferably used.

As the solvent, a solvent described in paragraphs 0054 and 0055 of US2005/282073A can also be used, and the contents of this specification are incorporated in the present disclosure.

In addition, as the solvent, an organic solvent (high-boiling-point solvent) having a boiling point of 180° C. to 250° C. can also be used, as necessary.

In a case where the above-described photosensitive composition includes a solvent, the photosensitive resin composition according to the embodiment of the present disclosure may include only one kind of the solvent, or may include two or more kinds thereof.

The solid content of the above-described photosensitive composition is preferably 5% by mass to 80% by mass, more preferably 5% by mass to 40% by mass, and particularly preferably 5% by mass to 30% by mass with respect to the total mass of the photosensitive composition.

For example, from the viewpoint of coatability, the viscosity of the above-described photosensitive composition at 25° C. is preferably 1 mPa·s to 50 mPa·s, more preferably 2 mPa·s to 40 mPa·s, and still more preferably 3 mPa·s to 30 mPa·s.

The viscosity is measured using a viscometer. As the viscometer, for example, a viscometer (product name: VISCOMETER TV-22) manufactured by Toki Sangyo Co. Ltd. can be suitably used. However, the viscometer is not limited thereto.

For example, from the viewpoint of coatability, the surface tension of the above-described photosensitive composition at 25° C. is preferably 5 mN/m to 100 mN/m, more preferably 10 mN/m to 80 mN/m, and still more preferably 15 mN/m to 40 mN/m.

The surface tension is measured using a tensiometer. As the tensiometer, for example, a tensiometer (product name: Automatic Surface Tensiometer CBVP-Z) manufactured by Kyowa Interface Science Co., Ltd. can be suitably used. However, the tensiometer is not limited thereto.

It is not necessary that the solvent used in forming the photosensitive layer is completely removed. For example, the content of the solvent in the photosensitive layer is preferably 5% by mass or less, more preferably 1% by mass or less, and particularly preferably 0.5% by mass or less with respect to the total mass of the photosensitive layer.

<<Tint>>

The photosensitive layer is preferably achromatic. Specifically, in CIE1976 (L*, a*, b*) color space of the total reflected light (incidence angle: 8°, light source: D-65 (visual field: 2°)), the L* value is preferably 10 to 90, the a* value is preferably −1.0 to 1.0, and the b* value is preferably −1.0 to 1.0.

<<Impurities and the Like>>

The photosensitive layer may include a predetermined amount of impurities.

Examples of the impurities in the photosensitive layer include metal impurities, and specific examples thereof include sodium, potassium, magnesium, calcium, iron, manganese, copper, aluminum, titanium, chromium, cobalt, nickel, zinc, tin, ions of these, and halide ions (chloride ion, bromide ion, iodide ion, and the like).

The content of impurities in the photosensitive layer is preferably 80 ppm or less, more preferably 10 ppm or less, and particularly preferably 2 ppm or less on a mass basis. As the lower limit value of the content of impurities in the photosensitive layer, the content of impurities in the photosensitive layer may be 1 ppb or more or 0.1 ppm or more on a mass basis.

Examples of a method for controlling the content of impurities in the photosensitive layer within the above-described range include one or more method of selecting a material with a low content of impurities as a raw material for the photosensitive layer, preventing the impurities from being mixed in a case of forming the photosensitive layer, and washing and removing the impurities in a case of forming the photosensitive layer. By such a method, the amount of impurities can be kept within the above-described range.

The impurities in the photosensitive layer can be quantified by a known method such as inductively coupled plasma (ICP) emission spectroscopy, atomic absorption spectroscopy, and ion chromatography.

Tt is preferable that the content of compounds such as benzene, formaldehyde, 1,3-butadiene, N,N-dimethylformamide, N,N-dimethylacetamide, and hexane is low in the photosensitive layer. The content of these compounds in the photosensitive layer is preferably 100 ppm or less, more preferably 20 ppm or less, and particularly preferably 4 ppm or less on a mass basis.

As the lower limit value of these compounds in the photosensitive layer, the content of these compounds in the photosensitive layer may be 10 ppb or more, or may be 100 ppb or more on a mass basis. The content of these compounds can be controlled in the same manner as the method used for controlling the content of metal impurities described above. In addition, the content of these compounds can be quantified by a known measurement method.

From the viewpoint of reliability and laminating property, the content of water in the photosensitive layer is preferably 0.01% to 1.0% by mass and more preferably 0.05% to 0.5% by mass with respect to the total mass of the photosensitive layer.

<Second Resin Layer>

The transfer film according to the embodiment of the present disclosure may further have a second resin layer between the temporary support and the photosensitive layer.

Examples of the second resin layer include a thermoplastic resin layer which will be described later, and an interlayer.

In addition, as the second resin layer the transfer film according to the embodiment of the present disclosure may have a thermoplastic resin layer or an interlayer between the temporary support and the photosensitive layer, or may have both a thermoplastic resin layer and an interlayer between the temporary support and the photosensitive layer.

—Thermoplastic Resin Layer—

The transfer film according to the embodiment of the present disclosure may further have a thermoplastic resin layer between the temporary support and the photosensitive layer.

In a case where the transfer film further has a thermoplastic resin layer, air bubbles due to lamination are hardly generated in a case where the transfer film is transferred to a substrate to form a laminate. In a case where this laminate is used in an image display device, image unevenness is hardly generated and excellent display properties are obtained.

The thermoplastic resin layer preferably has alkali solubility.

The thermoplastic resin layer functions as a cushion material which absorbs ruggedness of the surface of the substrate in a case of transfer.

The ruggedness of the surface of the substrate includes an image, an electrode, a wiring, and the like which are formed in advance.

The thermoplastic resin layer preferably has properties capable of being deformed in accordance with ruggedness.

The thermoplastic resin layer preferably includes an organic polymer substance described in JP1993-72724A (JP-H05-72724A), and more preferably includes an organic polymer substance having a softening point approximately 80° C. or lower by a Vicat method (specifically, polymer softening point measurement method using an American Society for Testing and Materials ASTM D1235).

The thickness of the thermoplastic resin layer is preferably 3 μm to 30 μm, more preferably 4 μm to 25 μm, and still more preferably 5 μm to 20 μm.

In a case where the thickness of the thermoplastic resin layer is 3 μm or more, followability with respect to the ruggedness of the surface of the substrate is improved, and the ruggedness of the surface of the substrate can be effectively absorbed.

In a case where the thickness of the thermoplastic resin layer is 30 μm or less, since the manufacturing suitability is more improved, for example, burden of the drying (so-called drying for removing the solvent) in a case of applying and forming the thermoplastic resin layer on the temporary support is further reduced, and the development time of the thermoplastic resin layer after the transfer is further shortened.

The thickness of the thermoplastic resin layer is obtained as an average value of 5 random points measured by cross-sectional observation with a scanning electron microscope (SEM).

The thermoplastic resin layer can be formed by applying and, as necessary, drying a composition for forming a thermoplastic resin layer including a solvent and a thermoplastic organic polymer on the temporary support.

Specific examples of coating and drying methods in the forming method of the thermoplastic resin layer are the same as the specific examples of coating and drying in the forming method of the photosensitive layer, respectively.

The solvent is not particularly limited as long as the solvent dissolves the polymer component forming the thermoplastic resin layer.

Examples of the solvent include organic solvents (for example, methyl ethyl ketone, cyclohexanone, propylene glycol monomethyl ether acetate, n-propanol, and 2-propanol).

The viscosity of the thermoplastic resin layer measured at 100° C. is preferably 1,000 Pa·s to 10,000 Pa·s. In addition, the viscosity of the thermoplastic resin layer measured at 100° C. is preferably lower than the viscosity of the photosensitive layer measured at 100° C.

—Interlayer—

The transfer film according to the embodiment of the present disclosure may further have an interlayer between the temporary support and the photosensitive layer.

In a case where the transfer film according to the embodiment of the present disclosure has the thermoplastic resin layer, the interlayer is preferably disposed between the thermoplastic resin layer and the photosensitive layer.

Examples of a component included in the interlayer include at least one polymer selected from the group consisting of polyvinyl alcohol, polyvinylpyrrolidone, and cellulose.

In addition, as the interlayer, a component described in JP1993-72724A (JP-H05-72724A) as a “separation layer” can also be used.

In a case of producing the transfer film having the thermoplastic resin layer, the interlayer, and the photosensitive layer on the temporary support in this order, for example, the interlayer can be formed by applying and, as necessary, drying a composition for forming an interlayer including a solvent which does not dissolve the thermoplastic resin layer, and the above-described polymer as the component of the interlayer.

Specifically, first, the composition for forming a thermoplastic resin layer is applied and dried on the temporary support to form the thermoplastic resin layer. Next, the composition for forming an interlayer is applied on the formed thermoplastic resin layer and dried as necessary to form the interlayer. Next, a photosensitive resin composition (so-called a composition for forming a photosensitive layer) including an organic solvent is applied on the formed interlayer and dried to form the photosensitive layer. The organic solvent included in the composition for forming a photosensitive layer is preferably an organic solvent which does not dissolve the interlayer.

Specific examples of coating and drying methods in the forming method of the interlayer are the same as the specific examples of coating and drying in the forming method of the photosensitive layer, respectively.

—Antistatic Layer—

The transfer film according to the embodiment of the present disclosure may further include an antistatic layer between the temporary support and the photosensitive layer.

In a case where the transfer film according to the embodiment of the present disclosure further includes an antistatic layer, since it is possible to suppress generation of static electricity in a case of peeling off the film or the like disposed on the antistatic layer, and also to suppress generation of static electricity due to rubbing against equipment, other films, or the like, for example, it is possible to suppress occurrence of defect in an electronic device.

The antistatic layer is a layer having antistatic properties, and contains an antistatic agent. The antistatic agent is not particularly limited, and a known antistatic agent can be applied. The antistatic agent is preferably at least one compound selected from the group consisting of an ionic liquid, an ionic conductive polymer, an ionic conductive filler, and an electrically conductive polymer, and more preferably an electrically conductive polymer.

As the electrically conductive polymer, a known electrically conductive polymer can be applied as long as the effect of the antistatic layer is not impaired.

Examples of the electrically conductive polymer include polythiophene, polyaniline, polypyrrole, polyethyleneimine, and arylamine-based polymers.

As the polythiophene, a polymer compound including poly(3,4-ethylenedioxythiophene) (PEDOT) is preferable, and a conductive polymer compound consisting of poly(3,4-ethylenedioxythiophene) and polystyrene sulfonic acid (hereinafter, abbreviated as PEDOT/PSS) is particularly preferable. Examples of a commercially available product of the polythiophene include Clevios series (Heraeus Holding), ORGACON series (AGFA Materials Japan .LTD), Denatron P-502RG, Denatron PT-432ME, and Denatron N8-2-1 (Nagase ChemteX Corporation), and SEPLEGYDA AS-X, SEPLEGYDA AS-D, SEPLEGYDA AS-H, SEPLEGYDA AS-F, SEPLEGYDA HC-R, SEPLEGYDA HC-A, SEPLEGYDA SAS-P, SEPLEGYDA SAS-M, and SEPLEGYDA SAS-F (Shin-Etsu Polymer Co., Ltd.).

Examples of the polyaniline include ORMECON series (Nissan Chemical Corporation).

Examples of the polypyrrole include product numbers 482552 and 735817 (Aldrich-Sigma, Co. LLC.).

In the present disclosure, as the electrically conductive polymer, the above-described commercially available products can be preferably used.

The antistatic layer may contain only one kind of antistatic agent, or may contain two or more kinds of antistatic agents.

The surface electrical resistance value of the antistatic layer is preferably 1.0×10¹² Ω/sq or less, and is preferably 1.0×10⁸ Ω/sq or more.

The thickness of the antistatic layer is preferably 0.4 μm or less. The lower limit value of the thickness of the antistatic layer is not particularly limited, but the thickness of the antistatic layer may be, for example, 10 nm or more.

<Refractive Index Adjusting Layer>

The transfer film according to the embodiment of the present disclosure may further have a refractive index adjusting layer between the temporary support and the photosensitive layer.

The refractive index adjusting layer is not limited, and a known refractive index adjusting layer can be applied. Examples of a material contained in the refractive index adjusting layer include a binder and particles.

The binder is not limited, and a known binder can be applied. Examples of the binder include the above-described binder polymer.

The particles are not limited, and known particles can be applied. Examples of the particles include zirconium oxide particles (ZrO₂ particles), niobium oxide particles (Nb₂O₅ particles), titanium oxide particles (TiO₂ particles), and silicon dioxide particles (SiO₂ particles).

In addition, the refractive index adjusting layer preferably contains a metal oxidation inhibitor. In a case where the refractive index adjusting layer contains a metal oxidation inhibitor, oxidation of metal in contact with the refractive index adjusting layer can be suppressed.

Preferred examples of the metal oxidation inhibitor include a compound having an aromatic ring including a nitrogen atom in the molecule. Specific examples of the metal oxidation inhibitor include imidazole, benzimidazole, tetrazole, mercaptothiadiazole, and benzotriazole.

The refractive index of the refractive index adjusting layer is preferably 1.50 or more, more preferably 1.55 or more, and particularly preferably 1.60 or more.

In addition, the upper limit of the refractive index of the refractive index adjusting layer is not particularly limited, but is preferably 2.10 or less and more preferably 1.85 or less.

The thickness of the refractive index adjusting layer is preferably 500 nm or less, more preferably 110 nm or less, and particularly preferably 100 nm or less.

In addition, the thickness of the refractive index adjusting layer is preferably 20 nm or more and more preferably 50 nm or more.

The thickness of the refractive index adjusting layer is obtained as an average value of 5 random points measured by cross-sectional observation with a scanning electron microscope (SEM).

A method for forming the refractive index adjusting layer is not limited, and a known method can be applied. Examples of the method for forming the refractive index adjusting layer include a method using a composition for a refractive index adjusting layer. For example, the composition for a refractive index adjusting layer is applied on an object to be coated, and the composition is dried as necessary to form a refractive index adjusting layer.

Examples of a method for producing the composition for a refractive index adjusting layer include a method of mixing the above-described components and a solvent. The mixing method is not limited, and a known method can be applied.

The solvent is not limited, and a known solvent can be applied. Examples of the solvent include water, and organic solvents described in the above section of “method for forming the photosensitive layer”.

As the coating method and drying method, the coating method and drying method described in the above section of “method for forming the photosensitive layer” can be applied, respectively.

<Protective Film>

The transfer film according to the embodiment of the present disclosure may further have a protective film on a side of the photosensitive layer opposite to the temporary support.

The above-described protective film is preferably an outermost layer on the surface opposite to the temporary support in the transfer film according to the embodiment of the present disclosure.

Examples of the protective film include a polyethylene terephthalate film, a polyethylene film, a polypropylene film, a polystyrene film, and a polycarbonate film.

As the protective film, for example, films described in paragraphs 0083 to 0087 and 0093 of JP2006-259138A may be used.

The thickness of the protective film is preferably 1 to 100 μm, more preferably 5 to 50 μm, still more preferably 5 to 40 μm, and particularly preferably 15 to 30 μm. Here, the thickness of the protective film is preferably 1 μm or more in terms of excellent mechanical hardness, and is preferably 100 μm or less in terms of relatively low cost.

In order to make it easier to peel off the protective film from the photosensitive layer, it is preferable that the adhesive force between the protective film and the photosensitive layer is smaller than the adhesive force between the temporary support and the photosensitive layer or the second resin layer.

In addition, the number of fisheyes with a diameter of 80 μm or more in the protective film is preferably 5 pieces/m² or less. Here, the “fisheye” means that, in a case where a material is hot-melted, kneaded, extruded, biaxially stretched, cast or the like to produce a film, foreign substances, undissolved substances, oxidatively deteriorated substances, and the like included in the material are incorporated into the film.

The number of particles having a diameter of 3 μm or more included in the protective film is preferably 30 particles/mm² or less, more preferably 10 particles/mm² or less, and still more preferably 5 particles/mm² or less. As a result, it is possible to suppress defects caused by ruggedness due to the particles included in the protective film being transferred to the photosensitive layer.

In the protective film, from the viewpoint of imparting take-up property, the arithmetic average roughness Ra on a surface opposite to a surface in contact with the photosensitive layer is preferably 0.01 μm or more, more preferably 0.02 μm or more, and still more preferably 0.03 μm or more. On the other hand, as the upper limit value of the arithmetic average roughness Ra on the surface opposite to the surface in contact with the photosensitive layer, the arithmetic average roughness Ra is preferably less than 0.50 μm, more preferably 0.40 μm or less, and still more preferably 0.30 μm.

In the protective film, from the viewpoint of suppressing defects during transfer, the arithmetic average roughness Ra on the surface in contact with the photosensitive layer is preferably 0.01 μm or more, more preferably 0.02 μm or more, and still more preferably 0.03 μm or more. On the other hand, as the upper limit value of the arithmetic average roughness Ra on the surface in contact with the photosensitive layer, the arithmetic average roughness Ra is preferably less than 0.50 μm, more preferably 0.40 μm or less, and still more preferably 0.30 μm.

—Specific Example of Transfer Film—

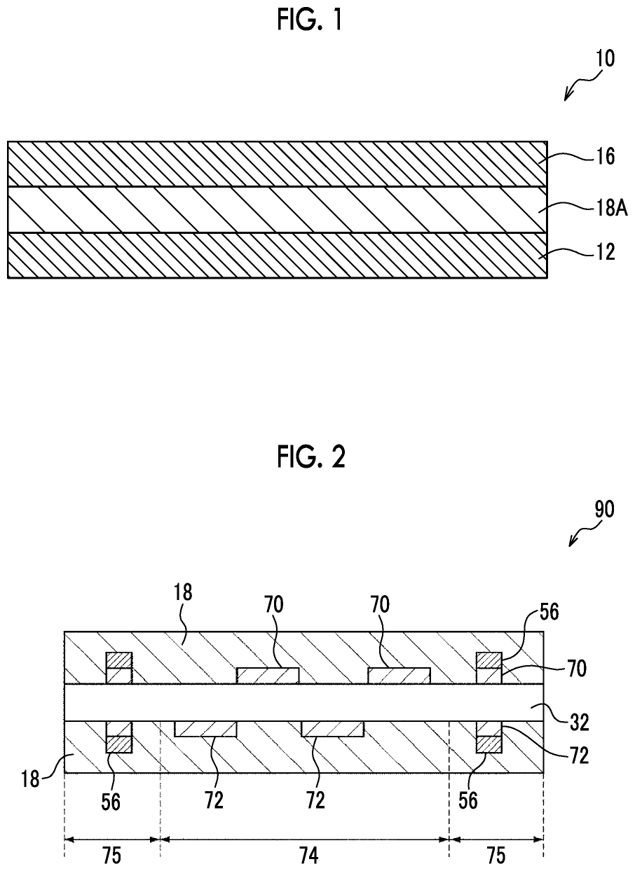

FIG. 1 is a schematic cross sectional view of a transfer film 10 which is a specific example of the transfer film according to the embodiment of the present disclosure. As shown in FIG. 1, the transfer film 10 has a laminated structure of temporary support 12/photosensitive layer 18A/protective film 16 (that is, laminated structure in which a temporary support 12, a photosensitive layer 18A, and a protective film 16 are arranged in this order).

However, the transfer film according to the embodiment of the present disclosure is not limited to the transfer film 10, and for example, the protective film 16 may be omitted.

A manufacturing method of the transfer film 10 is not particularly limited.

The manufacturing method of the transfer film 10, for example, includes a step of forming the photosensitive layer 18A on the temporary support 12, and a step of forming the protective film 16 on the photosensitive layer 18A in this order.

The manufacturing method of the transfer film 10 may include a step of volatilizing ammonia described in a paragraph 0056 of WO2016/009980A, between the step of forming the photosensitive layer 18A and the step of forming the protective film 16.

(Laminate and Capacitive Input Device)

The laminate according to the embodiment of the present disclosure includes, in the following order, a substrate, a silver conductive material, and a cured resin layer, in which an amount of free chloride ions included in the cured resin layer is 20 ppm or less, and a C log P value of a cured resin component included in the cured resin layer is 2.75 or more.

With regard to the above-described amount of free chloride ions included in the above-described cured resin layer, and the above-described C log P value of the cured resin component included in the cured resin layer, the preferred ranges are the same as the above-described amount of free chloride ions included in the above-described photosensitive layer, and the above-described mass content average value of C log P values in all the binder polymer and polymerizable compound included in the above-described photosensitive layer. In addition, the measuring method is also as described above.

The capacitive input device according to the present disclosure preferably includes the laminate according to the embodiment of the present disclosure.

In addition, the above-described capacitive input device is preferably a touch panel. That is, the touch panel according to the embodiment of the present disclosure preferably includes the laminate according to the embodiment of the present disclosure.

The substrate is preferably a substrate including an electrode of the capacitive input device.

The electrode of the capacitive input device may be a transparent electrode pattern or a lead wire.

In the laminate, the electrode of the capacitive input device is preferably an electrode pattern and more preferably a transparent electrode pattern.

It is preferable that the laminate according to the embodiment of the present disclosure includes a substrate, a transparent electrode pattern, a second resin layer disposed to be adjacent to the transparent electrode pattern, and a photosensitive layer disposed to be adjacent to the second resin layer, in which a refractive index of the second resin layer is higher than a refractive index of the photosensitive layer.

The refractive index of the second resin layer is preferably 1.6 or more. In addition, the upper limit of the refractive index of the second resin layer is not particularly limited, but is preferably 2.10 or less and more preferably 1.85 or less.

In a case where the laminate has the above-described configuration, covering property of the transparent electrode pattern is improved.

As the substrate, a glass substrate or a resin substrate is preferable.

In addition, the substrate is preferably a transparent substrate and more preferably a transparent resin substrate.

The refractive index of the substrate is preferably 1.50 to 1.52.

As the glass substrate, tempered glass such as GORILLA GLASS (registered trademark) manufactured by Corning Incorporated can be used.

As the resin substrate, at least one of a component with no optical strains or a component having high transparency is preferably used, and examples thereof include a substrate formed of a resin such as polyethylene terephthalate (PET), polyethylene naphthalate (PEN), polycarbonate (PC), triacetyl cellulose (TAC), polyimide (PI), polybenzoxazole (PBO), and cycloolefin polymer (COP).

As a material of the transparent substrate, a material described in JP2010-86684A, JP2010-152809A, and JP2010-257492A is preferable.

The silver conductive material is not particularly limited, and a known silver conductive material can be used.

The shape of the silver conductive material on the substrate is not particularly limited, and may be provided as a layer on one entire surface of the above-described substrate, or may have a desired patterned shape. Examples thereof include a mesh-shaped transparent electrode shape, and a wire shape such as a lead wire (so-called lead-out wire) disposed on a frame portion of the touch panel.

Among these, the silver conductive material preferably includes silver nanowires, and is more preferably a layer (silver nanowire layer) including silver nanowires. In addition, the above-described silver nanowire layer preferably has a desired patterned shape.

Examples of the shape of the silver nanowires include a cylindrical shape, a rectangular parallelepiped shape, and a columnar shape having a polygonal cross section. The silver nanowires preferably have at least one shape of a cylindrical shape or a columnar shape having a polygonal cross section in applications where high transparency is required.

The cross-sectional shape of the silver nanowires can be observed using, for example, a transmission electron microscope (TEM).

The diameter (so-called minor axis length) of the silver nanowires is not particularly limited, but from the viewpoint of transparency, for example, is preferably 50 nm or less, more preferably 35 nm or less, and still more preferably 20 nm or less.

From the viewpoint of oxidation resistance and durability, the lower limit of the diameter of the silver nanowires is preferably, for example, 5 nm or more.

The length (so-called major axis length) of the silver nanowires is not particularly limited, but from the viewpoint of conductivity, for example, is preferably 5 μm or more, more preferably 10 μm or more, and still more preferably 30 μm or more.

From the viewpoint of suppressing formation of aggregates in the manufacturing process, the upper limit of the length of the silver nanowires is preferably, for example, 1 mm or less.

The diameter and length of the silver nanowires can be measured using, for example, a transmission electron microscope (TEM) or an optical microscope.

Specifically, the diameter and length of 300 randomly selected silver nanowires are measured from the silver nanowires magnified and observed using a transmission electron microscope (TEM) or an optical microscope. Values obtained by arithmetically averaging the measured values are defined as the diameter and length of the silver nanowires.

The content of the silver nanowires in the silver nanowire layer is not particularly limited, but from the viewpoint of transparency and conductivity, is preferably 1% by mass to 99% by mass and more preferably 10% by mass to 95% by mass with respect to the total mass of the silver nanowire layer.

The silver nanowire layer may include a binder (also referred to as a “matrix”) as necessary.

The binder is a solid material in which the silver nanowires are dispersed or embedded.

Examples of the binder include polymer materials and inorganic materials.

As the binder, a material having light-transmitting property is preferable.

Examples of the polymer material include (meth)acrylic resins [for example, poly(methyl methacrylate)], polyesters [for example, polyethylene terephthalate (PET)], polycarbonates, polyimides, polyamides, polyolefins (for example, polypropylene), polynorbornenes, cellulose compounds, polyvinyl alcohol (PVA), and polyvinylpyrrolidone.

Examples of the cellulose compound include hydroxypropylmethyl cellulose (HPMC), hydroxyethyl cellulose (HEC), methyl cellulose (MC), hydroxypropyl cellulose (HPC), and carboxymethyl cellulose (CMC).

In addition, the polymer material may be a conductive polymer material.

Examples of the conductive polymer material include polyaniline and polythiophene.

Examples of the inorganic material include silica, mullite, and alumina.

In addition, as the binder, those described in paragraphs 0051 and 0052 of JP2014-212117A can also be used.

In a case where the silver nanowire layer includes a binder, the silver nanowire layer may include only one kind of the binder, or may include two or more kinds thereof.

In a case where the silver nanowire layer includes a binder, the content of the binder in the silver nanowire layer is preferably 1% by mass to 99% by mass and more preferably 5% by mass to 80% by mass with respect to the total mass of the silver nanowire layer.

The thickness of the silver nanowire layer is not particularly limited, but from the viewpoint of transparency and conductivity, is preferably 1 nm to 400 nm and more preferably 10 nm to 200 nm. Within the above-described range, low resistance electrode can be formed relatively easily.

The thickness of the silver nanowire layer is measured by the following method.

In a cross-sectional observation image of the silver nanowire layer in a thickness direction, the arithmetic average value of the thickness of the silver nanowire layer measured at five randomly selected points is obtained, and the obtained value is defined as the thickness of the silver nanowire layer. The cross-sectional observation image of the silver nanowire layer in the thickness direction can be obtained by using a scanning electron microscope (SEM).

In addition, the width of the silver nanowire layer can also be measured in the same manner as the measuring method of the thickness of the silver nanowire layer.

The above-described cured resin layer is preferably a layer obtained by curing the photosensitive layer in the transfer film according to the embodiment of the present disclosure.

In addition, the shape of the above-described cured resin layer is not particularly limited, and may have a desired patterned shape.

Further, the above-described cured resin layer may have an opening portion.

The opening portion can be formed by dissolving an unexposed portion of the photosensitive layer with a developer.

The above-described cured resin layer preferably includes a cured resin obtained by curing a curable component (the polymerizable compound, the photopolymerization initiator, the thermal crosslinking compound, and the like) in the above-described photosensitive layer by a reaction such as polymerization.

In addition, the preferred aspect of components other than the curable component in the above-described cured resin layer is the same as the preferred aspect in the above-described photosensitive layer, and the preferred content of these components in the above-described cured resin layer is also the same as in the preferred aspect in the above-described photosensitive layer.

In addition, the preferred thickness of the above-described cured resin layer is the same as the preferred thickness of the above-described photosensitive layer.

The touch panel may include a refractive index adjusting layer.

The preferred aspect of the refractive index adjusting layer is the same as the preferred aspect of the refractive index adjusting layer which can be included in the transfer film.

The refractive index adjusting layer may be formed by applying and drying a composition for forming the refractive index adjusting layer, or may be formed by transferring the refractive index adjusting layer of the transfer film having the refractive index adjusting layer.

The aspect in which the touch panel includes the refractive index adjusting layer has an advantage in which the silver conductive material and the like are hardly visible (that is, wire visibility is prevented).

As the wire for a touch panel, for example, the lead wire (lead-out wire) disposed on the frame portion of the touch panel is used. As a material of the wire for a touch panel, metal is preferable. Examples of a metal which is the material of the wire for a touch panel include gold, silver, copper, molybdenum, aluminum, titanium, chromium, zinc, manganese, and alloy formed of two or more kinds of these metal elements. Among these, as the metal which is the material of the wire for a touch panel, copper, molybdenum, aluminum, or titanium is preferable, and from the viewpoint of low electric resistance, copper is more preferable. On the other hand, since copper is easily oxidized and discolored, it is preferable to perform treatment with a treatment liquid described later.

[Antioxidant Treatment]

An antioxidant treatment step is a step of treating a copper film with a treatment liquid containing at least one azole compound (that is, specific azole compound) selected from the group consisting of an imidazole compound, a triazole compound, a tetrazole compound, a thiazole compound, and a thiadiazole compound, thereby subjecting a copper wire for a touch panel to antioxidant treatment.

In the antioxidant treatment step, discoloration of the copper wire for a touch panel can be suppressed by treating the copper film with a treatment liquid containing a specific azole compound.

The specific azole compound is not particularly limited.

From the viewpoint of further suppressing the discoloration of the copper wire, the pKa of a conjugate acid of the specific azole compound is preferably 4.00 or less and more preferably 2.00 or less.

The lower limit of the pKa of the conjugate acid of the specific azole compound is not particularly limited.

In the present specification, the pKa of the conjugate acid is a calculated value obtained by ACD/ChemSketch (ACD/Labs 8.00, Release Product Version: 8.08).

The molecular weight of the specific azole compound is not particularly limited, but for example, is preferably 1000 or less.

As a specific example of the specific azole compound, the above description of the heterocyclic compound is preferably applied.

Among these, as the specific azole compound, from the viewpoint of further suppressing the discoloration of the copper wire for a touch panel, at least one azole compound selected from the group consisting of a triazole compound and a tetrazole compound is preferable, at least one azole compound selected from the group consisting of 1,2,3-triazole, 1,2,4-triazole, 1,2,3-benzotriazole, and 5-amino-1H-tetrazole is more preferable, and at least one azole compound selected from the group consisting of 1,2,4-triazole and 5-amino-1H-tetrazole is still more preferable.

The treatment liquid may contain only one kind of the specific azole compound, or may contain two or more kinds thereof.

The content of the specific azole compound in the treatment liquid is preferably 0.005% by mass or more, more preferably 0.008% by mass or more, and still more preferably 0.01% by mass or more with respect to the total mass of the treatment liquid.

The upper limit of the content of the specific azole compound in the treatment liquid is not particularly limited, but from the viewpoint of solubility of the specific azole compound, is preferably 5% by mass or less.

The treatment liquid contains water.

The content of the water in the treatment liquid is not particularly limited, but for example, is preferably 70% by mass to 99.9% by mass, more preferably 90.0% by mass to 99.9% by mass, still more preferably 95.0% by mass to 99.9% by mass, and particularly preferably 98.0% by mass to 99.9% by mass with respect to the total mass of the treatment liquid.

The treatment liquid may contain an organic solvent having miscibility with water.

Examples of the organic solvent include methanol, ethanol, 2-propanol, 1-propanol, butanol, diacetone alcohol, ethylene glycol monomethyl ether, ethylene glycol monoethyl ether, ethylene glycol mono-n-butyl ether, benzyl alcohol, acetone, methyl ethyl ketone, cyclohexanone, ε-caprolactone, γ-butyrolactone, dimethylformamide, dimethylacetamide, hexamethylphosphoramide, ethyl lactate, methyl lactate, ε-caprolactam, and N-methylpyrrolidone.

In a case where the treatment liquid contains an organic solvent, the content of the organic solvent in the treatment liquid is preferably 0.1% by mass to 30% by mass with respect to the total mass of the treatment liquid.

The treatment liquid may contain a known surfactant.

In a case where the treatment liquid contains a surfactant, the content of the surfactant in the treatment liquid is preferably 0.01% by mass to 10% by mass with respect to the total mass of the treatment liquid.

Examples of the treatment method include methods such as puddle treatment, shower treatment, shower and spin treatment, and dip treatment.

The liquid temperature of the treatment liquid is preferably 20° C. to 40° C.

With regard to the structure of the touch panel, a structure of a capacitive input device described in JP2014-10814A and JP2014-108541A may be referred to.

The preferred aspects of the laminating, the pattern exposure, and the development will be described later.

—Specific Example of Touch Panel—

FIG. 2 is a schematic cross sectional view of a touch panel 90 which is a second specific example of the touch panel according to the embodiment of the present disclosure.

As shown in FIG. 2, the touch panel 90 has an image display region 74 and an image non-display region 75 (that is, frame portion).

In addition, the touch panel 90 includes the electrode for a touch panel on both surfaces of a substrate 32. Specifically, the touch panel 90 includes a first silver conductive material 70 on one surface of the substrate 32 and includes a second silver conductive material 72 on the other surface thereof.

In the touch panel 90, a lead wire 56 is connected to the first silver conductive material 70 and the second silver conductive material 72, respectively. The lead wire 56 is, for example, a copper wire or a silver wire.

In the touch panel 90, a silver conductive material protective film 18 is formed on one surface of the substrate 32 so as to cover the first transparent electrode pattern 70 and the lead wire 56, and the silver conductive material protective film 18 is formed on the other surface of the substrate 32 so as to cover the second silver conductive material 72 and the lead wire 56.

The refractive index adjusting layer of the first specific example may be formed on one surface of the substrate 32.

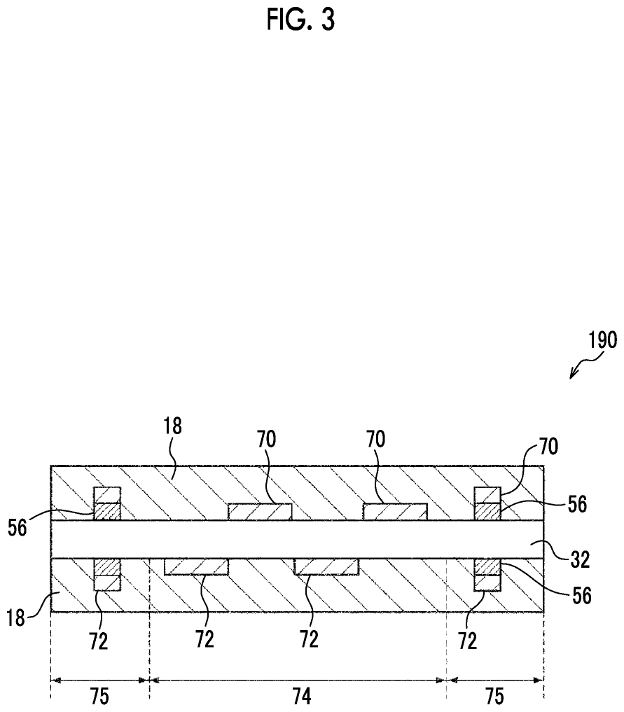

In addition, FIG. 3 is a schematic cross sectional view of a touch panel 190 which is a third specific example of the touch panel according to the embodiment of the present disclosure.

As shown in FIG. 3, the touch panel 190 has an image display region 74 and an image non-display region 75 (that is, frame portion).

In addition, the touch panel 190 includes the electrode for a touch panel on both surfaces of the substrate 32. Specifically, the touch panel 190 includes a first silver conductive material 70 on one surface of the substrate 32 and includes a second silver conductive material 72 on the other surface thereof.

In the touch panel 190, a lead wire 56 is connected to the first silver conductive material 70 and the second silver conductive material 72, respectively. The lead wire 56 is, for example, a copper wire or a silver wire. In addition, the lead wire 56 is formed inside surrounded by the silver conductive material protective film 18, and the first silver conductive material 70 or the second silver conductive material 72.

In the touch panel 190, a silver conductive material protective film 18 is formed on one surface of the substrate 32 so as to cover the first transparent electrode pattern 70 and the lead wire 56, and the silver conductive material protective film 18 is formed on the other surface of the substrate 32 so as to cover the second silver conductive material 72 and the lead wire 56.

The refractive index adjusting layer of the first specific example may be formed on one surface of the substrate 32.

(Manufacturing Method of Patterned Silver Conductive Material)

It is sufficient that the manufacturing method of a patterned silver conductive material according to the embodiment of the present disclosure is a method using the transfer film according to the embodiment of the present disclosure. However, it is preferable that the manufacturing method of a patterned silver conductive material according to the embodiment of the present disclosure includes, in the following order, a step of transferring at least the above-described photosensitive layer of the transfer film according to the embodiment of the present disclosure to a substrate having a silver conductive material on a surface (also referred to as a “photosensitive layer forming step”); a step of performing a pattern exposure of the above-described photosensitive layer (also referred to as a “pattern exposure step”); and a step of developing the above-described photosensitive layer to form a pattern (also referred to as a “development step”).

In addition, it is more preferable that the manufacturing method of a patterned silver conductive material according to the embodiment of the present disclosure includes, in the following order, a step of preparing a substrate, a step of forming an electrode for a touch panel on the substrate with a silver conductive material, and a step of forming a metal layer on the substrate having the electrode for a touch panel, in which the manufacturing method further includes a step of treating the metal layer with a treatment liquid containing at least one azole compound selected from the group consisting of an imidazole compound, a triazole compound, a tetrazole compound, a thiazole compound, and a thiadiazole compound, and a step of forming a wire for a touch panel from the metal layer, and the manufacturing method further includes, in the following order, a step of attaching at least the above-described photosensitive layer in the transfer film according to the embodiment of the present disclosure to the wire for a touch panel and the substrate having the electrode for a touch panel, a step of performing a pattern exposure of the above-described photosensitive layer, and a step of developing the above-described photosensitive layer to form a pattern.

In the above-described aspect, any one of the step of treatment or the step of forming the wire for a touch panel from the metal layer may be performed first.

Further, it is also preferable that the manufacturing method of a patterned silver conductive material according to the embodiment of the present disclosure includes, in the following order, a step of preparing a substrate, and a step of forming a metal layer on the substrate, in which the manufacturing method further includes a step of treating the metal layer with a treatment liquid containing at least one azole compound selected from the group consisting of an imidazole compound, a triazole compound, a tetrazole compound, a thiazole compound, and a thiadiazole compound, and a step of forming a wire for a touch panel from the metal layer, and the manufacturing method further includes, in the following order, a step of forming an electrode for a touch panel with a silver conductive material on the substrate on a side of the wire for a touch panel, a step of attaching at least the above-described photosensitive layer in the transfer film according to the embodiment of the present disclosure to the wire for a touch panel and the substrate having the electrode for a touch panel, a step of performing a pattern exposure of the above-described photosensitive layer, and a step of developing the above-described photosensitive layer to form a pattern.

In the above-described aspect, any one of the step of treatment or the step of forming the wire for a touch panel from the metal layer may be performed first.

Hereinafter, each step in the manufacturing method of a patterned silver conductive material according to the embodiment of the present disclosure will be described.

<Photosensitive Layer Forming Step>

The photosensitive layer forming step is a step of transferring at least the above-described photosensitive layer of the transfer film according to the embodiment of the present disclosure to a substrate having a silver conductive material on a surface.

In the photosensitive layer forming step, the photosensitive layer is formed on the surface by laminating the transfer film according to the embodiment of the present disclosure on the surface of the substrate which has a silver conductive material on a surface, on a side on which the silver conductive material is disposed, and transferring the photosensitive layer of the transfer film according to the embodiment of the present disclosure on the surface.

The laminating (so-called transfer of the photosensitive layer) can be performed using a known laminator such as a vacuum laminator or an auto-cut laminator.

As the laminating condition, a general condition can be applied.

The laminating temperature is preferably 80° C. to 150° C., more preferably 90° C. to 150° C., and still more preferably 100° C. to 150° C.

In a case of using a laminator including a rubber roller, the laminating temperature indicates a temperature of the rubber roller.

A temperature of the substrate in a case of laminating is not particularly limited.

The temperature of the substrate in a case of laminating is preferably 10° C. to 150° C., more preferably 20° C. to 150° C., and still more preferably 30° C. to 150° C.

In a case of using a resin substrate as the substrate, the temperature of the substrate in a case of laminating is preferably 10° C. to 80° C., more preferably 20° C. to 60° C., and still more preferably 30° C. to 50° C.

In addition, the linear pressure in a case of laminating is preferably 0.5 N/cm to 20 N/cm, more preferably 1 N/cm to 10 N/cm, and still more preferably 1 N/cm to 5 N/cm.

In addition, the transportation speed (laminating speed) in a case of laminating is preferably 0.5 m/min to 5 m/min and more preferably 1.5 m/min to 3 m/min.

In a case of using the transfer film having a laminated structure of protective film/photosensitive layer/interlayer/thermoplastic resin layer/temporary support, first, the protective film is peeled off from the transfer film to expose the photosensitive layer, the transfer film and the substrate are attached to each other so that the exposed photosensitive layer and the surface of the substrate on the side on which the silver conductive material is disposed are in contact with each other, and heating and pressurizing are performed. By such an operation, the photosensitive layer of the transfer film is transferred onto the surface of the substrate on the side on which the silver conductive material is disposed, and a laminate having a laminated structure of temporary support/thermoplastic resin layer/interlayer/photosensitive layer/silver conductive material/substrate is formed. In this laminated structure, the portion of “silver conductive material/substrate” is the substrate having a silver conductive material on the surface.

Thereafter, the temporary support is peeled off from the laminate, as necessary. However, the pattern exposure which will be described later can be also performed, by leaving the temporary support.

As an example of the method of transferring the photosensitive layer of the transfer film on the substrate and performing pattern exposure and development, a description described in paragraphs 0035 to 0051 of JP2006-23696A can also be referred to.

<Pattern Exposure Step>

The pattern exposure step is a step of performing a pattern exposure of the above-described photosensitive layer after the above-described photosensitive layer forming step.

The “pattern exposure” refers to exposure of the aspect of performing the exposure in a patterned shape, that is, the embodiment in which an exposed portion and an unexposed portion are present.

The exposed portion of the photosensitive layer on the substrate in the pattern exposure is cured and finally becomes the cured film.

Meanwhile, the unexposed portion of the photosensitive layer on the substrate in the pattern exposure is not cured, and is dissolved and removed with a developer in the subsequent development step. With the unexposed portion, the opening portion of the cured film can be formed after the development step.

The pattern exposure may be an exposure through a mask or may be a digital exposure using a laser or the like.

As a light source of the pattern exposure, a light source can be appropriately selected, as long as it can emit light at a wavelength region (for example, 365 nm or 405 nm) at which the photosensitive layer can be cured.

Examples of the light source include various lasers, a light emitting diode (LED), an ultra-high pressure mercury lamp, a high pressure mercury lamp, and a metal halide lamp.

The exposure amount is preferably 5 mJ/cm² to 200 mJ/cm² and more preferably 10 mJ/cm² to 200 mJ/cm².

In a case where the photosensitive layer is formed on the substrate using the transfer film, the pattern exposure may be performed after peeling the temporary support, or the temporary support may be peeled off after performing the pattern exposure before peeling off the temporary support.

In addition, in the exposure step, the heat treatment (so-called post exposure bake (PEB)) may be performed with respect to the photosensitive layer after the pattern exposure and before the development.

<Development Step>

The development step is a step of developing the above-described photosensitive layer after the above-described pattern exposure step (that is, by dissolving the unexposed portion in the pattern exposure in a developer) to form a pattern.

A developer used in the development is not particularly limited, and a well-known developer such as a developer disclosed in JP1993-72724A (JP-H05-72724A) can be used.

As the developer, an alkali aqueous solution is preferably used.

Examples of an alkali compound which can be included in the alkali aqueous solution include sodium hydroxide, potassium hydroxide, sodium carbonate, potassium carbonate, sodium hydrogen carbonate, potassium hydrogencarbonate, tetramethyl ammonium hydroxide, tetraethyl ammonium hydroxide, tetrapropyl ammonium hydroxide, tetrabutylammonium hydroxide, and choline (2-hydroxyethyltrimethylammonium hydroxide).

The pH of the alkali aqueous solution at 25° C. is preferably 8 to 13, more preferably 9 to 12, and particularly preferably 10 to 12.

The content of the alkali compound in the alkali aqueous solution is preferably 0.1% by mass to 5% by mass and more preferably 0.1% by mass to 3% by mass with respect to the total mass of the alkali aqueous solution.

The developer may include an organic solvent having miscibility with water.

Examples of the organic solvent include methanol, ethanol, 2-propanol, 1-propanol, butanol, diacetone alcohol, ethylene glycol monomethyl ether, ethylene glycol monoethyl ether, ethylene glycol mono-n-butyl ether, benzyl alcohol, acetone, methyl ethyl ketone, cyclohexanone, ε-caprolactone, γ-butyrolactone, dimethylformamide, dimethylacetamide, hexamethylphosphoramide, ethyl lactate, methyl lactate, ε-caprolactam, and N-methylpyrrolidone.

The concentration of the organic solvent is preferably 0.1% by mass to 30% by mass.

The developer may include a known surfactant.

The concentration of the surfactant is preferably 0.01% by mass to 10% by mass.

The liquid temperature of the developer is preferably 20° C. to 40° C.

Examples of the development method include methods such as puddle development, shower development, shower and spin development, and dip development.

In a case of the shower development, the unexposed portion of the photosensitive layer is removed by spraying the developer to the photosensitive layer after the pattern exposure as a shower.

In a case of using the transfer film including at least one of the photosensitive layer, the thermoplastic resin layer, or the interlayer, after the transfer of these layers onto the substrate and before the development of the photosensitive layer, an alkali solution having a low solubility of the photosensitive layer may be sprayed as a shower, and at least one of the thermoplastic resin layer or the interlayer (both layers, in a case where both layers are present) may be removed in advance, or the thermoplastic resin layer and the interlayer may be removed at the same time as the unexposed portion.

In addition, after the development, the development residue is preferably removed by spraying a washing agent with a shower and rubbing with a brush or the like.

The liquid temperature of the developer is preferably 20° C. to 40° C.

The development step may include a stage of performing the development, and a stage of performing the heat treatment (hereinafter, also referred to as “post baking”) with respect to the cured film obtained by the development.

In a case where the substrate is a resin substrate, a temperature of the post baking is preferably 100° C. to 160° C. and more preferably 130° C. to 160° C.

A resistance value of the transparent electrode pattern can also be adjusted by this post baking.

In a case where the photosensitive layer includes a carboxy group-containing (meth)acrylic resin, at least a part of the carboxy group-containing (meth)acrylic resin can be changed to carboxylic acid anhydride by the post baking. In a case of being changed in this way, developability of the photosensitive layer and hardness of the cured film are excellent.

The development step may include a stage of performing the development, and a stage of exposing the cured film obtained by the development (hereinafter, also referred to as “post exposure”).

In a case where the development step includes both a stage of performing the post exposure and a stage of performing the post baking, it is preferable to perform the post-baking after the post-exposure.

With regard to the pattern exposure and the development, for example, a description described in paragraphs 0035 to 0051 of JP2006-23696A can be referred to.

The manufacturing method of a patterned silver conductive material according to the embodiment of the present disclosure may include a step (so-called other steps) other than the steps described above.

Examples of the other step include a known step (for example, washing step) which may be provided in a normal photolithography step.

### EXAMPLES

Hereinafter, the present disclosure will be described in more detail with reference to Examples.

The material, the amount used, the ratio, the process contents, the process procedure, and the like shown in the following examples can be appropriately changed, within a range not departing from a gist of the present disclosure. Accordingly, the range of the present disclosure is not limited to specific examples shown below.

The C log P value and the mass content average value of C log P values in the examples were calculated by the methods described above.

<Measurement of Diameter and Major Axis Length of Silver Nanowire>

Using a transmission electron microscope (TEM; manufactured by JEOL Ltd., JEM-2000FX), 300 silver nanowires were observed, and the diameter and major axis length of each silver nanowire were measured. The diameter and major axis length of the silver nanowires were calculated by arithmetically averaging 300 measured values.

[Preparation of Coating Liquid for Forming Silver Nanowire Layer]

<Preparation of Additive Solution A>

0.51 g of silver nitrate was dissolved in 50 mL of pure water. 1 mol/L of aqueous ammonia was added to the obtained solution until the liquid became transparent. Thereafter, pure water was added to the obtained solution so that the total amount of the solution became 100 mL to prepare an additive solution A.

<Preparation of Additive Solution G>

0.5 g of glucose powder was dissolved in 140 mL of pure water to prepare an additive solution G.

<Preparation of Additive Solution H>

0.5 g of hexadecyl-trimethylammonium bromide (HTAB) powder was dissolved in 27.5 mL of pure water to prepare an additive solution H.

<Preparation of Coating Liquid for Forming Silver Nanowire Layer>

After putting pure water (410 mL) into a three-neck flask, the additive solution H (82.5 mL) and the additive solution G (206 mL) were added thereto with a funnel while stirring at 20° C. The additive solution A (206 mL) was added to the obtained solution at a flow rate of 2.0 mL/min and a stirring rotation speed of 800 rpm (revolutions per minutes; the same applies hereinafter). After 10 minutes, 82.5 mL of the additive solution H was added to the obtained solution. Thereafter, the obtained solution was heated to an internal temperature of 75° C. at 3° C./min. Thereafter, the stirring rotation speed was reduced to 200 rpm, and the solution was heated for 5 hours. After cooling the obtained solution, the solution was placed in a stainless steel cup, and ultrafiltration was performed using an ultrafiltration device in which an ultrafiltration module SIP1013 (manufactured by Asahi Kasei Corporation, molecular weight cut off: 6,000), a magnet pump, a stainless steel cup was connected with a silicon tube. In a case where the filtrate from the module reached 50 mL, 950 mL of distilled water was added to the stainless steel cup for washing. After repeating the above-described washing 10 times, concentration was performed until the amount of the solution reached 50 mL. The additive solution A, the additive solution Q and the additive solution H were repeatedly prepared by the above-described method and used for preparing a coating liquid for forming a silver nanowire layer.

The obtained concentrated solution was diluted with pure water and methanol (volume ratio of pure water and methanol: 60/40) to obtain a coating liquid for forming a silver nanowire layer.

[Production of Transparent Conductive Film]

Next, the coating liquid for forming a silver nanowire layer was applied to a cycloolefin polymer film. The amount of the coating liquid for forming a silver nanowire layer was set so that the wet film thickness was 20 μm. The layer thickness of the silver nanowire layer after drying was 30 nm, and the sheet resistance of the layer including the silver nanowire was 60Ω/□. The sheet resistance was measured using a noncontact eddy current-type resistance measuring instrument EC-80P (manufactured by NAPSON). In addition, the diameter of the silver nanowire was 17 nm, the major axis length thereof was 35 μm.

[Preparation of Coating Liquid for Forming Photosensitive Layer]

Coating liquids A-1 to A-20 for forming a photosensitive layer were prepared according to the description in Table 1 below. The numerical values in each component column in Table 1 represent the mass ratio of the total solid content in the coating liquid.

TABLE 1

| | | | Liquid | | Com- | Com- | Com- | Com- | Com- | Com- | Com- | Com- | Com- | Com- | Com- | Com- | Com- | Com- | Com- | Com- | |
|---|---|---|---|---|---|---|---|---|---|---|---|---|---|---|---|---|---|---|---|---|---|
| | | | concen- | | pound | pound | pound | pound | pound | pound | pound | pound | pound | pound | pound | pound | pound | pound | pound | pound | |
| | | | tration | | A-1 | A-2 | A-3 | A-4 | A-5 | A-8 | B-1 | B-2 | B-3 | B-4 | B-5 | C-1 | C-2 | C-3 | C-4 | D-1 | Layer |
| | | Coating | (solid | | (% by | (% by | (% by | (% by | (% by | (% by | (% by | (% by | (% by | (% by | (% by | (% by | (% by | (% by | (% by | (% by | thickness |
| | | liquid | content) | Solvent | mass) | mass) | mass) | mass) | mass) | mass) | mass) | mass) | mass) | mass) | mass) | mass) | mass) | mass) | mass) | mass) | (μm) |
| Example | 1 | A-1 | 30% | MEK | 54.6 | — | — | — | — | — | 21.9 | 21.8 | — | — | — | 0.5 | 1 | — | — | 0.2 | 4 |
| | 2 | A-2 | 30% | MEK | — | — | 54.6 | — | — | — | 21.9 | 21.8 | — | — | — | 0.5 | 1 | — | — | 0.2 | 4 |
| | 3 | A-3 | 30% | MEK | 19.7 | — | — | 39.4 | — | — | 19.6 | 19.6 | — | — | — | 0.5 | 1 | — | — | 0.2 | 4 |
| | 4 | A-4 | 30% | MEK | 54.6 | — | — | — | — | — | 21.6 | 21.8 | 0.3 | — | — | 0.5 | 1 | — | — | 0.2 | 4 |
| | 5 | A-5 | 30% | MEK | 54.6 | — | — | — | — | — | 21.6 | 21.8 | — | 0.3 | — | 0.5 | 1 | — | — | 0.2 | 4 |
| | 6 | A-6 | 30% | MEK | 88.5 | — | — | — | — | — | 9.8 | — | — | — | — | 0.5 | 1 | — | — | 0.2 | 4 |
| | 7 | A-7 | 30% | MEK | 68.8 | — | — | — | — | — | 9.8 | 10.8 | 8.9 | — | — | 0.5 | 1 | — | — | 0.2 | 4 |
| | 8 | A-8 | 30% | MEK | 39.4 | 36.4 | — | — | — | — | — | — | 22.6 | — | — | 0.5 | 1 | — | — | 0.2 | 4 |
| | 9 | A-1 | 1% | MEK | 54.6 | — | — | — | — | — | 21.9 | 21.8 | — | — | — | 0.5 | 1 | — | — | 0.2 | 0.05 |
| | 10 | A-1 | 1% | MEK | 54.6 | — | — | — | — | — | 21.9 | 21.8 | — | — | — | 0.5 | 1 | — | — | 0.2 | 0.04 |
| | 11 | A-1 | 30% | MEK | 54.6 | — | — | — | — | — | 21.9 | 21.8 | — | — | — | 0.5 | 1 | — | — | 0.2 | 10 |
| | 12 | A-1 | 30% | MEK | 54.6 | — | — | — | — | — | 21.9 | 21.8 | — | — | — | 0.5 | 1 | — | — | 0.2 | 4 |
| | 13 | A-11 | 30% | MEK | — | — | — | — | 61.5 | — | 18.5 | 18.5 | — | — | — | — | — | 1.3 | — | 0.2 | 8 |
| | 14 | A-12 | 30% | MEK | — | — | — | — | — | 61.5 | 18.5 | 18.5 | — | — | — | — | — | 1.3 | — | 0.2 | 8 |
| | 15 | A-13 | 30% | MEK | 58.1 | — | — | — | — | — | 25 | 16 | — | — | — | — | — | — | 0.7 | 0.2 | 4 |
| | 16 | A-14 | 30% | MEK | 58.1 | — | — | — | — | — | — | 16 | — | — | 25 | — | — | — | 0.7 | 0.2 | 4 |
| | 17 | A-15 | 30% | MEK | — | — | — | — | 58.1 | — | — | 16 | — | — | 25 | — | — | — | 0.7 | 0.2 | 4 |
| | 18 | A-16 | 30% | MEK | — | — | — | — | — | 58.1 | — | 16 | — | — | 25 | — | — | — | 0.7 | 0.2 | 4 |
| | 19 | A-17 | 30% | MEK | — | — | — | — | — | 58.1 | — | 16 | — | — | 25 | — | — | 0.7 | — | 0.2 | 4 |
| | 20 | A-18 | 30% | MEK | 56.35 | — | — | — | — | — | 10.8 | 18.9 | 0.15 | — | 12.5 | 0.25 | 0.5 | — | 0.35 | 0.2 | 4 |
| | 21 | A-19 | 30% | MEK | 56.35 | — | — | — | — | — | 10.8 | 18.9 | — | 0.15 | 12.5 | 0.25 | 0.5 | — | 0.35 | 0.2 | 4 |
| | 22 | A-20 | 30% | MEK | 58.1 | — | — | — | — | — | 25 | 16 | — | — | — | — | — | 0.35 | 0.35 | 0.2 | 4 |
| Compar- | 1 | A-9 | 30% | MEK | 68.8 | — | — | — | — | — | — | — | 29.5 | — | — | 0.5 | 1 | — | — | 0.2 | 4 |
| ative | 2 | A-10 | 30% | MEK | 78.6 | 14.8 | — | — | — | — | 4.9 | — | — | — | — | 0.5 | 1 | — | — | 0.2 | 4 |
| example | | | | | | | | | | | | | | | | | | | | | |

Details of the abbreviations shown in Table 1 are shown below.

<Binder Polymer>

Compound A-1: random copolymerized substance of benzyl methacrylate/methacrylic acid=72/28 (molar ratio), weight-average molecular weight: 37,000, C log P value=2.52

Compound A-2: polymethyl methacrylate, weight-average molecular weight: 25,000, C log P value=1.11

Compound A-3: random copolymerized substance of butyl methacrylate/methacrylic acid=59/41 (molar ratio), weight-average molecular weight: 25,000, C log P value=2.09

Compound A-4: random copolymerized substance of styrene/methyl methacrylate/methacrylic acid=34/26/40 (molar ratio), weight-average molecular weight: 25,000, C log P value=1.60

Compound A-5: cyclohexyl methacrylate/methyl methacrylate/methacrylic acid/methacrylic acid-glycidyl methacrylate adduct=51.5/2/26.5/20 (molar ratio), weight-average molecular weight: 27,000, C log P value=2.17

Compound A-8: styrene/methacrylic acid/dicyclopentadienyl methacrylate/methacrylic acid-glycidyl methacrylate adduct=41/24/15/20 (molar ratio), weight-average molecular weight: 19,000, C log P value=2.52

<Polymerizable Compound>

Compound B-1: 1,10-decanediol diacrylate, A-DOD-N, manufactured by Shin-Nakamura Chemical Co., Ltd., C log P value=5.13

Compound B-2: mixture of dipentaerythritol hexaacrylate/dipentaerythritol pentaacrylate, KAYARAD DPHA76, manufactured by Nippon Kayaku Co., Ltd., C log P value=5.08

Compound B-3: urethane acrylate 8UX-015A, manufactured by Taisei Fine Chemical Co., Ltd., C log P value=8.34

Compound B-4: polybasic acid-modified acrylic oligomer TO-2349 (monomer having a carboxy group (a mixture of a pentafunctional ethylenically unsaturated compound and a hexafunctional ethylenically unsaturated compound), manufactured by Toagosei Co., Ltd.), C log P value=4.63

Compound B-5: 1,9-nonanediol diacrylate, A-NOD-N, manufactured by Shin-Nakamura Chemical Co., Ltd., C log P value=4.60

<Photopolymerization Initiator>

Compound C-1: 1-[9-ethyl-6-(2-methylbenzoyl)-9H-carbazole-3-yl]ethanone-1-(O-acetyloxime), Irgacure OXE-02, manufactured by BASF SE

Compound C-2: 2-methyl-1-(4-methylthiophenyl)-2-morpholinopropan-1-one, Irgacure 907, manufactured by BASF SE

Compound C-3: [8-[5-(2,4,6-trimethylphenyl)-11-(2-ethylhexyl)-11H-benzo[a]carbazoyl][2-(2,2,3,3-tetrafluoro propoxy)phenyl]methanone-(O-acetyloxime) [product name: IRGACURE (registered trademark) OXE-03, manufactured by BASF SE]

Compound C-4: 2-(dimethylamino)-2-[(4-methylphenyl)methyl]-1-[4-(4-morpholinyl)phenyl]-1-butanone [product name: IRGACURE (registered trademark) 379EG, manufactured by BASF SE]

<Surfactant>

Compound D-1: nonionic fluorine surfactant, MEGAFACE F551A, manufactured by DIC Corporation

<Solvent>

MEK: methyl ethyl ketone

[Preparation of Coating Liquid for Forming Resin Layer]

Coating liquids B-1 and B-2 for forming a resin layer were prepared according to the description in Table 2 below. The numerical values in each component column in Table 2 represent the mass ratio of the total solid content in the coating liquid.

TABLE 2

| | | | | | | | | | | | | | Layer |
|---|---|---|---|---|---|---|---|---|---|---|---|---|---|
| | Coating | Concentration | | Compound A-1 | Compound A-5 | Compound A-6 | Compound A-7 | Compound B-3 | Compound B-4 | Compound B-6 | Compound D-1 | Compound D-2 | thickness |
| | liquid | (solid content) | Solvent | (% by mass) | (% by mass) | (% by mass) | (% by mass) | (% by mass) | (% by mass) | (% by mass) | (% by mass) | (% by mass) | (μm) |
| Resin | B-1 | 30% | MEK | 12.4 | 49.6 | — | — | 11.3 | 3.8 | 22.7 | 0.2 | — | 6 |
| layer 1 | | | | | | | | | | | | | |
| Resin | B-2 | 5% | Water | — | — | 68.4 | 31.5 | — | — | — | — | 0.1 | 1 |
| layer 2 | | | | | | | | | | | | | |

Details of the abbreviations shown in Table 2 other than those described above are shown below.

<Binder Polymer>

Compound A-5: cyclohexyl methacrylate/methyl methacrylate/methacrylic acid/methacrylic acid-glycidyl methacrylate adduct=51.5/2/26.5/20 (molar ratio), weight-average molecular weight: 27,000

Compound A-6: polyvinyl alcohol, PVA205, manufactured by Kuraray Co., Ltd.

Compound A-7: polyvinylpyrrolidone, PVPK30, manufactured by NIPPON SHOKUBAI CO., LTD.

<Polymerizable Compound>

Compound B-6: bifunctional alicyclic acrylate monomer, tricyclodecanedimethanol diacrylate, NK ESTER A-DCP, manufactured by Shin-Nakamura Chemical Co., Ltd.

<Surfactant>

Compound D-2: nonionic fluorine surfactant, MEGAFACE F444, manufactured by DIC Corporation

<Solvent>

Water: ion exchange water

### Examples 1 to 11 and Comparative Examples 1 and 2

<Production of Transfer Film>

The coating liquid B-1, which is a coating liquid for forming a resin layer, was applied on a polyethylene terephthalate film having a thickness of 16 μm (temporary support, LUMIRROR 16KS40 (manufactured by Toray Industries, Inc.)) using a slit-shaped nozzle, and was dried at 100° C., and the coating liquid B-2 was applied thereon again from above and dried at 100° C. to form a resin layer for transfer. The layer thickness after drying was adjusted to an amount that would be the layer thickness shown in Table 2.

The coating liquids A-1 to A-7 shown in Table, which are coating liquids for forming a photosensitive layer, were applied on the resin layer for transfer by the same method as for forming the resin layer, and dried at 100° C. to form a photosensitive layer. The layer thickness after drying was adjusted to an amount that would be the layer thickness shown in Table 1.

A polyethylene terephthalate film having a thickness of 16 μm (protective film, LUMIRROR 16KS40 (manufactured by Toray Industries, Inc.)) was pressure-bonded onto the photosensitive layer to prepare each transfer film.

### Example 12

A transfer film was produced by the same method as in Example 1, except that the resin layer for transfer was not formed.

### Examples 13 to 22

Transfer films were produced by the same method as in Example 1, except that the resin layer for transfer was not formed, and the coating liquid for forming a photosensitive layer shown in Table 1 was used.

[Production of Patterned Laminate]

—Laminate—

A laminate was obtained by laminating each photosensitive layer transfer material of Examples and Comparative Examples, from which the protective film had been peeled off, to the transparent conductive film coated with the silver nanowire (hereinafter, referred to as “lamination process” in this paragraph). The lamination process was performed using a vacuum laminator manufactured by MCK under conditions of a cycloolefin polymer film temperature: 40° C., a rubber roller temperature: 100° C., a linear pressure: 3 N/cm, and a transportation speed: 2 m/min.

—Exposure—

Next, using a proximity type exposure machine (manufactured by Hitachi High-Tech Electronics Engineering Co., Ltd.) including an ultra-high pressure mercury lamp, a surface of an exposure mask (specifically, quartz exposure mask having a pattern for forming a transparent electrode protective film) and the temporary support were closely attached, and the photosensitive layer was exposed in a patterned shape with an exposure amount of 100 mJ/cm² (exposure with i ray) through the temporary support.

—Development and Rinse—

After peeling off the temporary support, development treatment was performed at 32° C. in a 1% by mass aqueous solution of sodium carbonate for 60 seconds. After the development treatment, the residue was removed by injecting ultrapure water from an ultrapure water washing nozzle onto the patterned substrate. Thereafter, air was blown to remove the moisture to prepare a laminate in which the photosensitive layer was patterned.

<Measurement of Amount of Free Chloride Ions>

The amount of free chloride ions included in the photosensitive layer was measured by ion chromatography by preparing a sample for measurement as shown below.

—Production of Single Layer Transfer Film for Measurement—

The material A-1 to A-7, A-11, or A-12, which is a coating liquid for forming a photosensitive layer, was applied on a polyethylene terephthalate film having a thickness of 16 μm (temporary support, LUMIRROR 16KS40 (manufactured by Toray Industries, Inc.)) using a slit-shaped nozzle, and was dried at 100° C. to form a single layer transfer resin layer for measurement. The thickness after drying was adjusted to the amount shown in Table 2.

A polyethylene terephthalate film having a thickness of 16 μm (protective film, LUMIRROR 16KS40 (manufactured by Toray Industries, Inc.)) was pressure-bonded onto the photosensitive layer to prepare each single layer transfer film.

—Collection of Sample for Measuring Amount of Free Chloride Ions from Transfer Film—

The protective film was peeled off, the photosensitive layer on the transfer film was laminated on glass, and the temporary support was peeled off to transfer the photosensitive layer. Thereafter, 100 mg of the transferred photosensitive layer was collected.

—Production of Sample for Evaluating Amount of Halogen in Cured Resin Layer of Laminate—

The protective film of the transfer film was peeled off, the photosensitive layer side was laminated on glass, and the temporary support was peeled off to transfer the photosensitive layer. The lamination process was performed using a vacuum laminator manufactured by MCK under conditions of a cycloolefin polymer film temperature: 40° C., a rubber roller temperature: 100° C., a linear pressure: 3 N/cm, and a transportation speed: 2 m/min.

Next, the entire photosensitive layer was exposed through the temporary support using a proximity type exposure machine (manufactured by Hitachi High-Tech Electronics Engineering Co., Ltd.) including an ultra-high pressure mercury lamp with an exposure amount of 100 mJ/cm² (exposure with i ray).

After peeling off the temporary support, development treatment was performed at 32° C. in a 1% by mass aqueous solution of sodium carbonate for 60 seconds. After the development treatment, ultrapure water was injected onto the glass with a photosensitive layer from an ultrahigh pressure washing nozzle. Thereafter, air was blown to remove the moisture to produce a cured resin layer for evaluation.

100 mg of the cured resin layer was scraped off and collected.

—Method of Preparing Collected Sample—

100 mg of the collected sample was dissolved in 5 mL of propylene glycol monomethyl ether acetate. 5 mL of ultrapure water was added thereto, and the mixture was stirred for 2 hours. The mixture was left to stand for 12 hours or more, 1 mL of the aqueous layer was collected, and 9 mL of ultrapure water was added thereto to prepare a sample for measurement.

—Measurement of Amount of Free Chloride Ions—

An ion chromatograph was used for the measurement. Measurement conditions such as a measuring device are as described below.
Ion chromatograph device: IC-2010 (manufactured by Tosoh Corporation)
Analytical column: TSKgel SuperIC-Anion HS
Guard column: TSKgel guardcolumn SuperIC-A HS
Eluent: 1.7 mmol/L NaHCO₃ aqueous solution+1.8 mmol/L Na₂CO₃ aqueous solution
Flow rate: 1.2 mL/min
Temperature: 30° C.
Injection amount: 30 μL
Suppressor gel: TSKgel suppress IC-A
Detection: electrical conductivity (measured using a suppressor)

<Evaluation>

—Heat Test—

The produced laminate was heated at a temperature of 145° C. for 25 minutes using a convection oven.

—Wet Heat Test—

The produced laminate was tested for 80 hours at a temperature of 85° C. and a humidity of 85% RH using a constant temperature and humidity chamber.

—Resistance Measurement—

The sheet resistance of the produced laminate was measured using a noncontact eddy current-type resistance measuring instrument EC-80P (manufactured by NAPSON). 9 points were measured within a 10 cm square, and the average value thereof was used as the measured value.

The produced laminate was measured before and after the heat test or the wet heat test, and evaluated by the following A to D from the rate of change of the resistance value before and after the test. The rate of change was calculated by subtracting the resistance value before the test from the resistance value after the test and dividing the amount of increase in the resistance value by the resistance value before the test.

A: rate of change was 0% to 5%.

B: rate of change was more than 5% and 10% or less.

C: rate of change was more than 10% and 15% or less.

D: rate of change was more than 15%.

The evaluation results are summarized in Table 3.

TABLE 3

| | Formulation | | | | | | |
|---|---|---|---|---|---|---|---|
| | Transfer film | | Laminate | | | | |
| | (before curing) | | (after curing) | | | | |
| | | Average mass | | | Layer | Evaluation result | |
| | Amount of free | content of | Amount of free | | thickness of | Resistance | |
| | chloride ions of | ClogP of | chloride ions of | ClogP of | photosensitive | change | Resistance |
| | photosensitive layer | photosensitive | cured resin layer | cured resin | resin layer | after heat | change after |
| | (ppm) | layer | (ppm) | layer | (μm) | test | wet heat test |
| Example 1 | Less than 0.5 | 3.67 | Less than 0.5 | 3.67 | 4 | A | A |
| Example 2 | Less than 0.5 | 3.43 | Less than 0.5 | 3.43 | 4 | A | A |
| Example 3 | Less than 0.5 | 3.18 | Less than 0.5 | 3.18 | 4 | A | A |
| Example 4 | 1 | 3.68 | 1 | 3.68 | 4 | A | A |
| Example 5 | 1 | 3.67 | 1 | 3.67 | 4 | A | A |
| Example 6 | Less than 0.5 | 2.78 | Less than 0.5 | 2.78 | 4 | A | C |
| Example 7 | 6.5 | 3.59 | 6.5 | 3.59 | 4 | B | B |
| Example 8 | 16 | 3.33 | 16 | 3.33 | 4 | C | C |
| Example 9 | Less than 0.5 | 3.67 | Less than 0.5 | 3.67 | 0.05 | A | A |
| Example 10 | Less than 0.5 | 3.67 | Less than 0.5 | 3.67 | 0.04 | A | B |
| Example 11 | Less than 0.5 | 3.67 | Less than 0.5 | 3.67 | 10 | A | A |
| Example 12 | Less than 0.5 | 3.67 | Less than 0.5 | 3.67 | 4 | A | A |
| Example 13 | Less than 0.5 | 3.27 | Less than 0.5 | 3.27 | 8 | A | A |
| Example 14 | Less than 0.5 | 3.49 | Less than 0.5 | 3.49 | 8 | A | A |
| Example 15 | Less than 0.5 | 3.59 | Less than 0.5 | 3.59 | 4 | A | A |
| Example 16 | Less than 0.5 | 3.46 | Less than 0.5 | 3.46 | 4 | A | A |
| Example 17 | Less than 0.5 | 3.25 | Less than 0.5 | 3.25 | 4 | A | A |
| Example 18 | Less than 0.5 | 3.46 | Less than 0.5 | 3.46 | 4 | A | A |
| Example 19 | Less than 0.5 | 3.46 | Less than 0.5 | 3.46 | 4 | A | A |
| Example 20 | 0.5 | 3.57 | 0.5 | 3.57 | 4 | A | A |
| Example 21 | 0.5 | 3.56 | 0.5 | 3.56 | 4 | A | A |
| Example 22 | Less than 0.5 | 3.59 | Less than 0.5 | 3.59 | 4 | A | A |
| Comparative | 23 | 4.27 | 23 | 4.27 | 4 | D | D |
| example 1 | | | | | | | |
| Comparative | Less than 0.5 | 2.44 | Less than 0.5 | 2.44 | 4 | A | D |
| example 2 | | | | | | | |

The “mass content average value of C log P value in photosensitive layer” shown in Table 3 is the “mass content average value of C log P values in all the binder polymer and polymerizable compound included in the photosensitive layer”, and the “C log P value of cured resin layer” is the “C log P value of the cured resin component included in the cured resin layer”.

From the results shown in Table 3, as compared with the transfer films and laminates of Comparative Examples 1 and 2, in the transfer films and laminates of Examples 1 to 22, which are the transfer film for a silver conductive material protective film and laminate according to the embodiment of the present disclosure, it was found that the resistance change of the silver conductive material after the wet heat test was small.

Further, from the results shown in Table 3, in the transfer films and laminates of Examples 1 to 22, which are the transfer film for a silver conductive material protective film and laminate according to the embodiment of the present disclosure, it was found that the resistance change of the silver conductive material after the heat test was also small.

### Examples 101 to 106

<Production of Laminate for Evaluation>

A cycloolefin polymer (COP) film having a thickness of 100 μm was prepared as a transparent substrate. Next, a copper film was formed on one side of the substrate by a sputtering method to a thickness of 500 nm to produce a laminate having a laminated structure of copper film/substrate.

<Treatment of Laminate>

As a treatment liquid for the laminate produced above, treatment liquids C-1 to C-5 having the compositions shown in Table 4 below were prepared. Specifically, the specific azole compound was added to ion exchange water, and the mixture was stirred and mixed for 30 minutes to prepare a treatment liquid.

Next, the copper film side of the above-described laminate was showered for 40 seconds with the treatment liquid prepared above. After the treatment, the laminate was washed with pure water, air was blown to remove water, and heat treatment was performed at 80° C. for 1 minute to obtain a treated laminate.

<Etching of Copper Film>

Next, using a dry film resist with a negative type acrylic photosensitive layer which could be developed with a 1% by mass sodium carbonate aqueous solution, a resist layer having a thickness of 1 μm was transferred to the surface of the laminate produced above on the copper film side to obtain a laminate having a laminated structure of resist layer/copper film/substrate. Next, the surface of the obtained laminate on the resist layer side was exposed with a metal halide lamp through a mask, and the laminate was immersed in a 1% by mass sodium carbonate aqueous solution to perform development treatment to the resist layer.

Next, the copper film in a portion where the patterned resist layer was not laminated was removed by etching using a ferric chloride aqueous solution as an etchant, and then the resist layer was peeled off using a stripper.

As a result, a laminate in which the copper film (that is, wire) was formed on a peripheral portion on the transparent substrate was obtained.

<Formation of Silver Nanowire Layer Patterned in Touch Panel Electrode Pattern>

Next, the coating liquid for forming a silver nanowire layer prepared above was applied to the copper film (that is, wire) side of the laminate obtained above, and heated at 80° C. for 1 minute to produce a laminate having a laminated structure of silver nanowire layer/copper film (that is, wire)/substrate. The amount of the coating liquid for forming a silver nanowire layer was set so that the wet film thickness was 20 μm, the layer thickness of the silver nanowire layer after drying was 30 nm, and the diameter of the silver nanowire was 17 nm and the major axis length thereof was 35 μm.

Next, using a dry film resist with a negative type acrylic photosensitive layer which could be developed with a 1% by mass sodium carbonate aqueous solution, a resist layer having a thickness of 1 μm was transferred to the surface of the laminate produced above on the silver nanowire layer side to obtain a laminate having a laminated structure of resist layer/silver nanowire layer/copper film (that is, wire)/substrate. Next, the surface of the obtained laminate on the resist layer side was exposed with a metal halide lamp through a mask of the touch panel electrode pattern, and the laminate was immersed in a 1% by mass sodium carbonate aqueous solution to perform development treatment to the resist layer.

Next, the silver nanowire layer and silver nanowire layer/copper film in a portion where the patterned resist layer was not laminated were removed by etching using a ferric chloride aqueous solution as an etchant, and then the resist layer was peeled off using a stripper.

<Laminate of Transfer Film>

The protective film of the transfer film shown in Table 4 was peeled off, the photosensitive layer side was laminated on the silver nanowire layer side of the laminate treated above, and the temporary support was peeled off to transfer the photosensitive layer. The lamination process was performed using a vacuum laminator manufactured by MCK under conditions of a cycloolefin polymer film temperature: 40° C., a rubber roller temperature: 100° C., a linear pressure: 3 N/cm, and a transportation speed: 2 m/min.

Next, using a proximity type exposure machine (manufactured by Hitachi High-Tech Electronics Engineering Co., Ltd.) including an ultra-high pressure mercury lamp, the photosensitive layer was exposed in a patterned shape through the temporary support with an exposure amount of 60 mJ/cm² (i ray) through a mask of protective film pattern.

After peeling off the temporary support, development treatment was performed at 32° C. in a 1% by mass aqueous solution of sodium carbonate for 60 seconds to remove the photosensitive layer at a connection portion with the outside. After the development treatment, ultrapure water was injected onto the glass with a photosensitive layer from an ultrahigh pressure washing nozzle, and air was blown to remove the moisture.

Next, the photosensitive layer was further exposed to an exposure amount of 375 mJ/cm² without an exposure mask, and then heat-cured by heating at 140° C. for 20 minutes, thereby producing a laminate having a laminated structure of cured resin layer in which photosensitive layer was cured/silver nanowire layer/copper film (that is, wire)/substrate.

<Discoloration Evaluation of Copper>

After the laminate produced above was left to stand in an environment of 85° C. and 85% RH for 100 hours, the copper film (that is, wire) portion was observed from the cured resin layer side through the cured resin layer using an optical microscope (magnification: 50 times), and evaluation was performed based on the following evaluation standard.

A: no discolored portion was confirmed.

B: proportion of the discolored portion was 50% or less of the copper film (that is, wire).

C: proportion of the discolored portion was more than 50% and 80% or less of the copper film (that is, wire).

D: proportion of the discolored portion was more than 80% of the copper film (that is, wire).

The evaluation results are summarized in Table 4.

TABLE 4

| | | | Composition of treatment liquid (% by mass) | | | | |
|---|---|---|---|---|---|---|---|
| | | | Specific azole compound | | | | |
| | | | Benzimidazole | | | | Evaluation result |
| | Transfer | Treatment | compound | 1,2,4-triazole | 5-amino-1H-tetrazole | Ion exchange | Discoloration of |
| | film | liquid | pKa 5.67 | pKa 2.70 | pKa 1.29 | water | copper |
| Example | Example | — | — | — | — | — | D |
| 101 | 13 | | | | | | |
| Example | Example | C-1 | 0.1 | — | — | 99.9 | C |
| 102 | 13 | | | | | | |
| Example | Example | C-2 | — | 0.1 | — | 99.9 | B |
| 103 | 13 | | | | | | |
| Example | Example | C-3 | — | — | 0.1 | 99.9 | A |
| 104 | 13 | | | | | | |
| Example | Example | C-4 | — | — | 1 | 99 | A |
| 105 | 13 | | | | | | |
| Example | Example | C-4 | — | — | 1 | 99 | A |
| 106 | 14 | | | | | | |

The pKa values shown in Table 4 represent the pKa of the conjugate acid.

The disclosure of Japanese Patent Application No. 2019-058924 filed on Mar. 26, 2019, the disclosure of Japanese Patent Application No. 2019-148852 filed on Aug. 14, 2019, and the disclosure of Japanese Patent Application No. 2019-167254 filed on Sep. 13, 2019 are incorporated in the present specification by reference.

All documents, patent applications, and technical standards described in the present specification are incorporated herein by reference to the same extent as in a case of being specifically and individually noted that individual documents, patent applications, and technical standards are incorporated by reference.

What is claimed is:

1. A transfer film for a silver conductive material protective film, comprising:
a temporary support; and
a photosensitive layer which is provided on the temporary support, and includes at least one selected from the group consisting of a binder polymer and a polymerizable compound, and a photopolymerization initiator,
wherein an amount of free chloride ions included in the photosensitive layer is 20 ppm or less, and
a mass content average value of C log P values in all the binder polymer and polymerizable compound included in the photosensitive layer is 2.75 or more.

2. The transfer film according to claim 1,
wherein the amount of free chloride ions is 15 ppm or less.

3. The transfer film according to claim 1,
wherein the amount of free chloride ions is 10 ppm or less.

4. The transfer film according to claim 1,
wherein the amount of free chloride ions is 5 ppm or less.

5. The transfer film according to claim 1,
wherein the mass content average value of C log P values in all the binder polymer and polymerizable compound included in the photosensitive layer is 3.15 or more.

6. The transfer film according to claim 1,
wherein a thickness of the photosensitive layer is in a range of 0.05 μm to 10 μm.

7. The transfer film according to claim 1, further comprising:
a second resin layer between the temporary support and the photosensitive layer.

8. The transfer film according to claim 1,
wherein the binder polymer in the photosensitive layer includes an alkali-soluble resin.

9. A manufacturing method of a patterned silver conductive material, comprising in the following order:
a step of transferring at least the photosensitive layer of the transfer film according to claim 1 to a substrate having a silver conductive material on a surface;
a step of performing a pattern exposure of the photosensitive layer; and
a step of developing the photosensitive layer to form a pattern.

10. A laminate comprising in the following order:
a substrate;
a silver conductive material; and
a cured resin layer,
wherein an amount of free chloride ions included in the cured resin layer is 20 ppm or less, and
a C log P value of a cured resin component included in the cured resin layer is 2.75 or more.

11. A touch panel comprising:
the laminate according to claim 10.

12. A manufacturing method of a patterned silver conductive material, comprising in the following order:
a step of preparing a substrate;
a step of forming an electrode for a touch panel on the substrate with a silver conductive material; and
a step of forming a metal layer on the substrate having the electrode for a touch panel,
wherein the manufacturing method further includes
a step of treating the metal layer with a treatment liquid containing at least one azole compound selected from the group consisting of an imidazole compound, a triazole compound, a tetrazole compound, a thiazole compound, and a thiadiazole compound, and
a step of forming a wire for a touch panel from the metal layer, and
the manufacturing method further includes, in the following order,
a step of attaching at least the photosensitive layer in the transfer film according to claim 1 to the wire for a touch panel and the substrate having the electrode for a touch panel,
a step of performing a pattern exposure of the photosensitive layer, and
a step of developing the photosensitive layer to form a pattern.

13. A manufacturing method of a patterned silver conductive material, comprising in the following order:
a step of preparing a substrate; and
a step of forming a metal layer on the substrate,
wherein the manufacturing method further includes
a step of treating the metal layer with a treatment liquid containing at least one azole compound selected from the group consisting of an imidazole compound, a triazole compound, a tetrazole compound, a thiazole compound, and a thiadiazole compound, and
a step of forming a wire for a touch panel from the metal layer, and
the manufacturing method further includes, in the following order,
a step of forming an electrode for a touch panel with a silver conductive material on the substrate on a side of the wire for a touch panel,
a step of attaching at least the photosensitive layer in the transfer film according to claim 1 to the wire for a touch panel and the substrate having the electrode for a touch panel,
a step of performing a pattern exposure of the photosensitive layer, and
a step of developing the photosensitive layer to form a pattern.

14. The manufacturing method of a patterned silver conductive material according to claim 12,
wherein a pKa of a conjugate acid of the at least one azole compound selected from the group consisting of an imidazole compound, a triazole compound, a tetrazole compound, a thiazole compound, and a thiadiazole compound is 4.00 or less.

15. The manufacturing method of a patterned silver conductive material according to claim 13,
wherein a pKa of a conjugate acid of the at least one azole compound selected from the group consisting of an imidazole compound, a triazole compound, a tetrazole compound, a thiazole compound, and a thiadiazole compound is 4.00 or less.
